(19) United States
(12) Patent Application Publication
(10) Pub. No.: US 2022/0209193 A1
(43) Pub. Date: Jun. 30, 2022

(54) DISPLAY PANEL, DISPLAY DEVICE INCLUDING THE SAME, AND METHOD FOR MANUFACTURING THE DISPLAY PANEL

(71) Applicant: Samsung Display Co., Ltd., Yongin-Si (KR)

(72) Inventor: Jaemin Shin, Yongin-si (KR)

(21) Appl. No.: 17/464,436

(22) Filed: Sep. 1, 2021

(30) Foreign Application Priority Data
Dec. 31, 2020 (KR) 10-2020-0189231

(51) Int. Cl. H01L 51/52; H01L 51/50; H01L 51/56

(52) U.S. Cl. CPC H01L 51/5268; H01L 2251/308; H01L 51/56; H01L 51/502

(57) ABSTRACT

A display panel capable of stretching and contracting, improving resolution and flexibility, and extending a display area, a display device including the display panel, and a method of manufacturing the display panel include: a substrate including a plurality of through portions and a plurality of base portions spaced apart from each other by the plurality of through portions, a pixel electrode disposed on the substrate, an opposite electrode disposed on the pixel electrode, and a light-emitting layer disposed between the pixel electrode and the opposite electrode and including an inorganic semiconductor material having a grain boundary.

### CROSS-REFERENCE TO RELATED APPLICATION

This application is based on and claims priority under 35 U.S.C. § 119 to Korean Patent Application No. 10-2020-0189231, filed on Dec. 31, 2020, in the Korean Intellectual Property Office, the disclosure of which is incorporated by reference herein in its entirety.

### BACKGROUND

### 1. Field

The present disclosure generally relates to a display panel and a method of manufacturing the same. More particularly, the present disclosure relates to a display device capable of improving resolution and flexibility and a method of manufacturing the same.

### 2. Description of the Related Art

Mobility based electronic devices have a wide range of uses. A tablet personal computer (PC) has been recently used as a mobile electronic device, in addition to a small electronic device such as a mobile phone.

The mobile electronic device includes a display device for providing visual information such as images or moving images to users in order to support various functions. In recent years, as other components for driving the display device become smaller, the proportion of the display device in an electronic device is gradually increasing.

In recent years, flexible display devices that may be bent, folded, or rolled in a roll shape have been researched and developed. Further, research and development on a stretchable display device that may be changed into various forms is actively progressing.

### SUMMARY

A conventional display device includes an organic light-emitting diode (OLED) as a light-emitting device, and because the OLED is vulnerable to oxygen and moisture, an organic encapsulation layer is provided to protect the OLED. However, when such an organic encapsulation layer is applied to a stretchable display device, the resolution and flexibility of the display device may be deteriorated.

One or more embodiments include a display panel in which a stretchable and contractible display panel employs an inorganic light-emitting device as a light-emitting device, thereby removing design restrictions due to an organic encapsulation layer, improving resolution and flexibility, and expanding a display area, a display device including the display panel, and a method of manufacturing the display panel. However, this is merely an example, and the scope of the disclosure is not limited thereto.

Additional aspects will be set forth in part in the description which follows and, in part, will be apparent from the description, or may be learned by practice of the presented embodiments of the disclosure.

According to one or more embodiments, a display panel includes a substrate including a plurality of through portions and a plurality of base portions spaced apart from each other by the plurality of through portions, a pixel electrode disposed on the substrate, an opposite electrode disposed on the pixel electrode, and a light-emitting layer disposed between the pixel electrode and the opposite electrode and including an inorganic semiconductor material having a grain boundary.

According to the present embodiment, the inorganic semiconductor material of the light-emitting layer may include polycrystalline aluminum nitride (AlN) doped with silicon (Si) or polycrystalline gallium nitride (GaN) doped with Si.

According to the present embodiment, a thickness of the light-emitting layer may be about 100 Å or less.

According to the present embodiment, the pixel electrode may include aluminum (Al) or gallium (Ga).

According to the present embodiment, the opposite electrode may include indium tin oxide (ITO), indium zinc oxide (IZO), zinc oxide (ZnO), indium oxide (In₂O₃), indium gallium oxide (IGO), or aluminum zinc oxide (AZO).

According to the present embodiment, the display panel may further include a light conversion layer disposed on the opposite electrode and overlapping the light-emitting layer.

According to the present embodiment, the light conversion layer may include a first light conversion layer, a second light conversion layer, and a third light conversion layer each having scattering particles, wherein the first, second, and third light conversion layers may further include first, second, and third quantum dots including a same material but having different sizes, respectively.

According to the present embodiment, the display panel may further include a capping layer disposed between the opposite electrode and the light conversion layer and contacting the opposite electrode and the light conversion layer, respectively.

According to the present embodiment, the substrate may further include a plurality of connecting portions extending in different directions from the plurality of base portions, respectively, wherein two adjacent base portions from among the plurality of base portions may be spaced apart from each other with any one of the plurality of through portions therebetween, and at least one of the plurality of connecting portions may connect the two adjacent base portions to each other.

According to the present embodiment, the substrate may include a front area in a center, side areas extending outward from edges of the front area, respectively, and corner areas connecting two adjacent side areas to among the side areas, wherein the plurality of through portions and the plurality of base portions of the substrate may be located in the corner area and may extend outward away from the front area.

According to one or more embodiments, a display device includes a display panel, and a cover window disposed on the display panel, wherein the display panel includes: a substrate having a plurality of through portions and a plurality of base portions spaced apart from each other by the plurality of through portions, a pixel electrode disposed on the substrate, an opposite electrode disposed on the pixel electrode, and a light-emitting layer disposed between the pixel electrode and the opposite electrode and including an inorganic semiconductor material having a grain boundary.

According to the present embodiment, the inorganic semiconductor material of the light-emitting layer may include polycrystalline AlN doped with Si or polycrystalline GaN doped with Si.

According to the present embodiment, a thickness of the light-emitting layer may be about 100 Å or less.

According to the present embodiment, the pixel electrode may include Al or Ga.

According to the present embodiment, the display device may further include a light conversion layer disposed on the opposite electrode and overlapping the light-emitting layer.

According to the present embodiment, the display device may further include a capping layer interposed between the opposite electrode and the light conversion layer and contacting the opposite electrode and the light conversion layer, respectively.

According to the present embodiment, the substrate may further include a plurality of connecting portions extending in different directions from the plurality of base portions, respectively, wherein two adjacent base portions from among the plurality of base portions may be apart from each other with any one of the plurality of through portions therebetween, and at least one of the plurality of connecting portions may connect the two adjacent base portions to each other.

According to the present embodiment, the substrate may include a front area in a center, side areas extending outward from edges of the front area, respectively, and a corner area disposed outside an area where two adjacent side areas meet each other from among the side areas, wherein the plurality of through portions and the plurality of base portions of the substrate may be located in the corner area and may extend outward away from the front area.

According to one or more embodiments, a method of manufacturing a display panel includes preparing a substrate including a plurality of through portions and a plurality of base portions spaced apart from each other by the plurality of through portions, forming a pixel electrode including Al or Ga disposed on the substrate, forming a light-emitting layer disposed on the pixel electrode, and forming an opposite electrode disposed on the light-emitting layer, wherein the forming of the light-emitting layer includes: forming a material layer including silicon nitride (SiNx) disposed on the pixel electrode, and irradiating a laser beam onto the material layer.

According to the present embodiment, a thickness of the material layer may be about 100 Å or less.

According to the present embodiment, the light-emitting layer may include an inorganic semiconductor material having polycrystalline AlN doped with Si or polycrystalline GaN doped with Si.

According to the present embodiment, the method of manufacturing a display panel may further include forming a capping layer disposed on the opposite electrode, and forming a light conversion layer overlapping the light-emitting layer on the capping layer, wherein the capping layer may contact the opposite electrode and the light conversion layer, respectively.

According to the present embodiment, the substrate may further include a plurality of connecting portions extending in different directions from the plurality of base portions, respectively, wherein two adjacent base portions from among the plurality of base portions may be apart from each other with any one of the plurality of through portions therebetween, and at least one of the plurality of connecting portions may connect the two adjacent base portions to each other.

According to the present embodiment, the substrate may include a front area in a center, side areas extending outward from edges of the front area, respectively, and corner areas connecting two adjacent side areas to among the side areas, wherein the plurality of through portions and the plurality of base portions of the substrate may be located in the corner area and may extend outward away from the front area.

These and/or other aspects will become apparent and more readily appreciated from the following description of the embodiments, taken in conjunction with the accompanying drawings.

These general and specific embodiments may be implemented by using a system, a method, a computer program, or a combination thereof.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view of a display device according to an embodiment;

FIG. 2 is a cross-sectional view of a display device according to an embodiment;

FIG. 3A is a plan view of a display panel according to an embodiment, and FIGS. 3B and 3C are plan views of an enlarged portion of the display panel of FIG. 3A;

FIG. 4 is an equivalent circuit diagram of one pixel circuit included in a display device according to an embodiment;

FIG. 5 is a cross-sectional view of a portion of a display panel according to an embodiment;

FIG. 6 is a cross-sectional view of a portion of a light conversion layer of a display panel according to an embodiment;

FIGS. 7A, 7B, 7C, 7D, 7E, and 7F are cross-sectional views illustrating a method of manufacturing a display panel according to an embodiment;

FIG. 8 is a cross-sectional view of a portion of a display panel according to an embodiment;

FIG. 9 is an enlarged plan view of a portion of a display panel according to another embodiment;

FIG. 10 is a cross-sectional view of a portion of the display panel of FIG. 9;

FIG. 11 is a perspective view of a display device according to another embodiment;

FIG. 12 is a plan view of a display panel according to another embodiment;

FIG. 13 is an enlarged plan view of a portion of the display panel of FIG. 12; and

FIGS. 14A and 14B are enlarged plan views of a portion of a display panel according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Since the disclosure may have diverse modified embodiments, certain embodiments are illustrated in the drawings and are described in the detailed description. An effect and a characteristic of the disclosure, and a method of accomplishing these will be apparent when referring to embodiments described with reference to the drawings. The present invention may, however, be embodied in many different forms and should not be construed as limited to the embodiments set forth herein.

Hereinafter, embodiments of the disclosure will be described in detail with reference to the accompanying drawings. The same reference numerals are used to denote the same elements, and repeated descriptions thereof will be omitted.

It will be understood that although the terms “first,” “second,” etc. may be used herein to describe various components, these components should not be limited by these terms.

An expression used in the singular encompasses the expression of the plural, unless it has a clearly different meaning in the context.

It will be further understood that the terms “comprises” and/or “comprising” used herein specify the presence of stated features or elements, but do not preclude the presence or addition of one or more other features or elements.

It will be understood that when a layer, region, or element is referred to as being “formed on” another layer, area, or element, it can be directly or indirectly formed on the other layer, region, or element. That is, for example, intervening layers, regions, or elements may be present.

Sizes of elements in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the specification, the term “A and/or B” refers to the case of A or B, or A and B. In the specification, the term “at least one of A and B” refers to the case of A or B, or A and B.

It will be understood that when a layer, region, or component is connected to another portion, the layer, region, or component may be directly connected to the portion, and/or an intervening layer, region, or component may exist, such that the layer, region, or component may be indirectly connected to the portion. For example, when a layer, region, or component is electrically connected to another portion, the layer, region, or component may be directly electrically connected to the portion and/or may be indirectly connected to the portion through another layer, region, or component.

An x-axis, a y-axis and a z-axis are not limited to three axes of the rectangular coordinate system and may be interpreted in a broader sense. For example, the x-axis, the y-axis, and the z-axis may be perpendicular to one another or may represent different directions that are not perpendicular to one another.

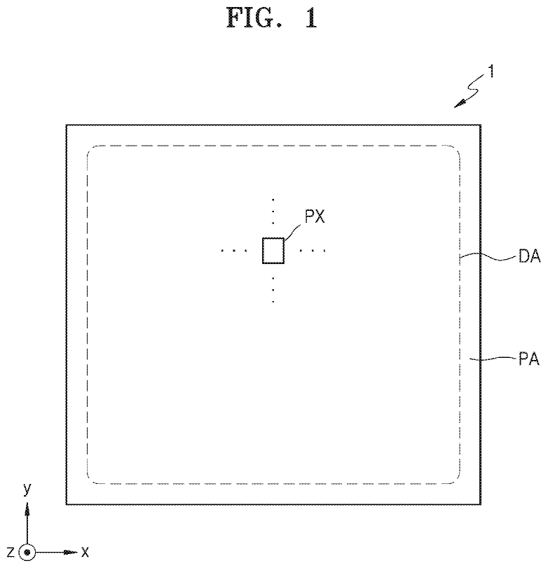

FIG. 1 is a plan view of a display device 1 according to an embodiment.

Referring to FIG. 1, the display device 1 may include a display area DA and a peripheral area PA outside the display area DA. The display device 1 may provide an image through an array of a plurality of pixels PX two-dimensionally arranged in the display area DA.

The peripheral area PA is an area that does not provide an image, and may entirely or partially surround the display area DA. A driver for providing an electric signal or power to a pixel circuit corresponding to each of the pixels PX may be disposed in the peripheral area PA. A pad, which is an area to which an electronic device or a printed circuit board may be electrically connected, may be in the peripheral area PA.

The display device 1 may be used as a display screen of various products such as a television, a laptop computer, a monitor, a billboard, and the Internet of Things (IOT), as well as portable electronic devices such as a mobile phone, a smart phone, a tablet personal computer (PC), a mobile communication terminal, an electronic notebook, an e-book, a portable multimedia player (PMP), a navigation, and an ultra mobile PC (UMPC). In addition, the display device 1 according to an embodiment may be used in a wearable device such as a smart watch, a watch phone, a spectacle-type display, and a head mounted display (HMD). Furthermore, the display device 1 according to an embodiment may be used as a dashboard of a vehicle, a center information display (CID) placed on a center fascia or a dashboard of a vehicle, a room mirror display that replaces side mirrors of a vehicle, and a display screen on a rear surface of a front seat as entertainment for a rear seat of a vehicle. In addition, the display device 1 according to an embodiment may be used as a multifunctional device having a sterilization and disinfection function using ultraviolet rays while displaying an image.

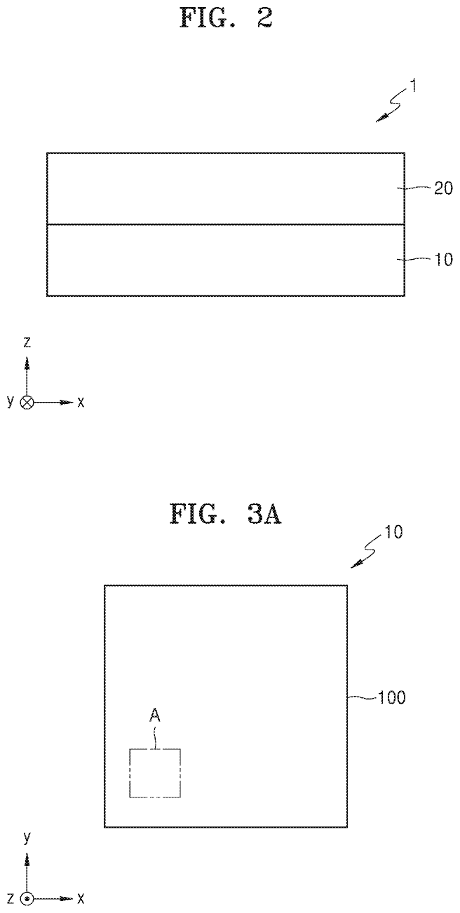

FIG. 2 is a cross-sectional view of the display device 1 according to an embodiment.

Referring to FIG. 2, the display device 1 may include a display panel 10 and a cover window 20. The cover window 20 may be on the display panel 10.

The display panel 10 may emit light through a plurality of pixels and display an image using the emitted light. A pixel may be defined as an area in which light is emitted by light-emitting devices provided in the display panel 10. The display panel 10 may include a display area defined by a plurality of pixels and a peripheral area outside the display area, wherein the display area of the display panel 10 may correspond to the display area DA (see FIG. 1) of the display device 1 described above, and the peripheral area PA of the display panel 10 may correspond to the peripheral area PA (see FIG. 1) of the display device 1 described above.

The cover window 20 may protect the display panel 10. In an embodiment, the cover window 20 may protect the display panel 10 while being easily bent according to an external force without occurrence of a crack or the like. The cover window 20 may be attached to the display panel 10 by a transparent adhesive member such as an optically clear adhesive (OCA) film.

The cover window 20 may include glass, sapphire, or plastic. In an embodiment, the cover window 20 may include ultra-thin glass (UTG). In another embodiment, the cover window 20 may include colorless transparent polyimide (CPI). In another embodiment, the cover window 20 may include a structure in which a flexible polymer layer is disposed on one surface of a glass substrate, or may include a structure provided only with a polymer layer.

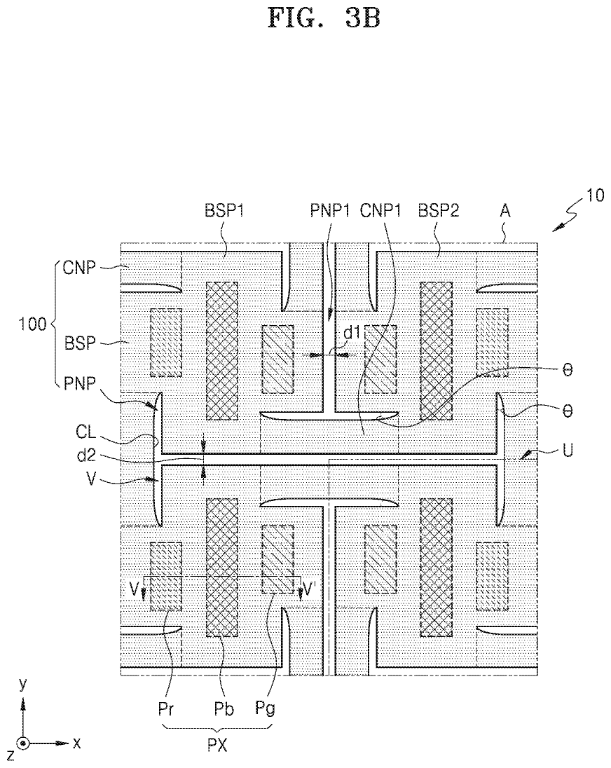

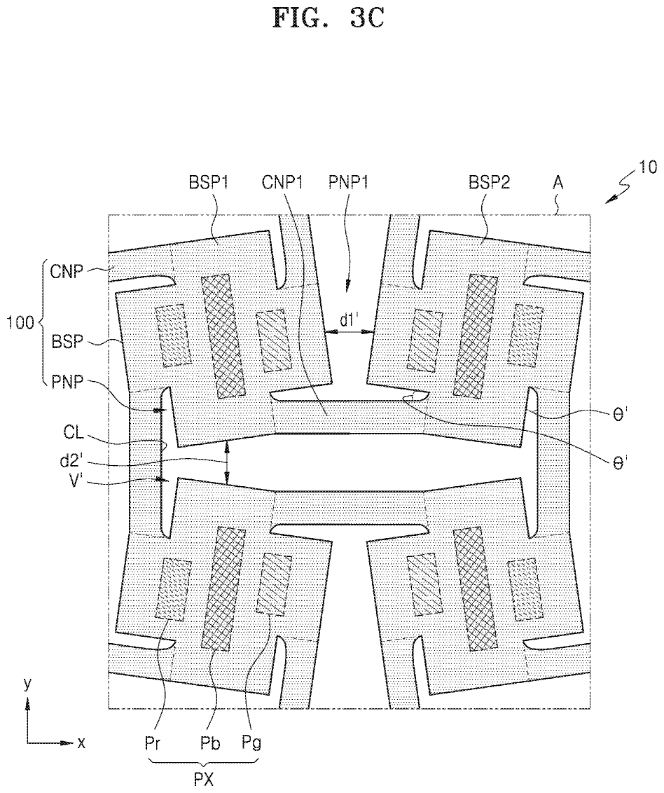

FIG. 3A is a plan view of a display panel according to an embodiment, and FIGS. 3B and 3C are plan views of an enlarged portion of the display panel of FIG. 3A. FIG. 3C illustrates that a portion of the display panel of FIG. 3B is stretched in various directions.

Referring to FIG. 3A, the display panel 10 may include a substrate 100. Various components (not shown) constituting the display panel 10 and a stacked structure thereof may be on the substrate 100.

The substrate 100 may include various materials such as glass, metal, or an organic material. In an embodiment, the substrate 100 may include a flexible material. For example, the substrate 100 may include ultra-thin flexible glass (e.g., a thickness of tens to several hundred μm) or a polymer resin. When the substrate 100 includes a polymer resin, the substrate 100 may include polyimide (PI). Alternatively, the substrate 100 may include polyethersulfone (PES), polyarylate, polyetherimide (PEI), polyethylene naphthalate (PEN), polyethylene terephthalate (PET), polyphenylene sulfide (PPS), polycarbonate (PC), cellulose triacetate (TAC), or/and cellulose acetate propionate (CAP).

Referring to FIGS. 3B and 3C, the substrate 100 of the display panel 10 may include a plurality of through portions PNP and a plurality of base portions BSP apart from each other by the plurality of through portions PNP. A through portion PNP may penetrate an upper surface of the substrate 100 and a lower surface opposite to the upper surface. Various components constituting the display panel 10 and a stacked structure thereof cannot be disposed on the through portion PNP of the substrate 100, and thus, the through portion PNP of the substrate 100 may be a through portion of the display panel 10. The substrate 100 includes the plurality of through portions PNP, thereby reducing the weight of the display panel 10 and extending and contracting in various directions. Accordingly, the flexibility of the display panel 10 may be improved.

Various components constituting the display panel 10 and a stacked structure thereof may be disposed on the base portions BSP of the substrate 100. Accordingly, the plurality of pixels PX of the display panel 10 may overlap the base portions BSP. In an embodiment, a pixel PX may include a red subpixel Pr, a green subpixel Pg, and a blue subpixel Pb. In another embodiment, the pixel PX may include the red subpixel Pr, the green subpixel Pg, the blue subpixel Pb, and a white subpixel. Hereinafter, a case where the pixel PX includes the red subpixel Pr, the green subpixel Pg, and the blue subpixel Pb will be described in detail.

In an embodiment, the plurality of base portions BSP spaced apart from each other may form flat grating patterns repeatedly arranged in a first direction (e.g., x direction or −x direction) and a second direction (e.g., y direction or −y direction) different from the first direction. In an embodiment, the first direction and the second direction may be directions orthogonal to each other. In another embodiment, the first direction and the second direction may form an obtuse angle or an acute angle. For example, adjacent base portions BSP may be spaced apart from each other by a first distance d1 in the first direction or by a second distance d2 in the second direction.

In an embodiment, the substrate 100 may further include a plurality of connecting portions CNP. Each of the connecting portions CNP extends in different directions from the plurality of base portions BSP. The plurality of connecting portions CNP may connect a plurality of adjacent base portions BSP to each other.

For example, two adjacent base portions BSP from among the plurality of base portions BSP may be spaced apart from each other with any one of the plurality of through portions therebetween, and at least one of the plurality of connecting portions may connect the two adjacent base portions to each other. For example, as shown in FIG. 3B, a first base portion BSP1 and a second base portion BSP2 adjacent to each other may be spaced apart from each other with a first through portion PNP1 therebetween, and a first connecting portion CNP1 may connect the first base portion BSP1 and the second base portion BSP2 to each other.

In an embodiment, each of the base portions BSP may have four connecting portions CNP connected thereto. The four connecting portions CNP connected to one base portion BSP may extend in different directions, and each of the connecting portions CNP may be connected to the other base portion BSP adjacent to the one base portion BSP described above. For example, one base portion BSP may be connected to the four base portions BSP through four connecting portions CNP arranged in a direction surrounding the one base portion BSP described above.

A plurality of base portions BSP and a plurality of connecting portions CNP may be continuously made of the same material. That is, a plurality of base portions BSP and a plurality of connecting portions CNP may be integrally formed.

Hereinafter, for convenience of description, one base portion BSP and connecting portions CNP connected thereto are referred to as one basic unit U, and the structure of the display panel 10 will be described in detail based on this. The basic unit U may be repeatedly disposed in the first direction (e.g., x direction or −x direction) and the second direction (e.g., y direction or −y direction), and it can be understood that the display device 1 is formed by connecting the repeatedly arranged basic units U to each other. Two adjacent basic units U may be symmetrical to each other. For example, in FIG. 3B, two basic units U horizontally adjacent to each other may be horizontally symmetrical with respect to an axis of symmetry located between the basic units U and parallel to the second direction. Similarly, in FIG. 3B, two basic units U vertically adjacent to each other may be vertically symmetrical with respect to an axis of symmetry located between the basic units U and parallel to the first direction.

Adjacent basic units U from among a plurality of basic units U, for example, the four basic units U shown in FIG. 3B, form a closed curve CL therebetween, and the closed curve CL may define one through portion PNP. For example, the through portion PNP may be defined as the closed curve CL including edges of a plurality of base portions BSP and edges of a plurality of connecting portions CNP. Each of the through portions PNP may provide a separation area V between the plurality of base portions BSP. That is, each of the through portions PNP may overlap the separation area V.

In addition, when an external force (a force such as bending, pulling, compressing, etc.) is applied to the display panel 10, shapes of separation areas V are changed, thereby giving the display panel 10 contraction and stretching characteristics. Furthermore, stress generation during deformation of the display panel 10 may be easily reduced, thereby preventing abnormal deformation of the display panel 10 and improving durability. Accordingly, user convenience may be improved when the display device 1 (see FIG. 1) including the display panel 10 is used, and the display device 1 may be easily applied to a wearable device.

An angle θ between an edge of the base portion BSP provided in one basic unit U and an edge of each connecting portion CNP may be an acute angle, and when an external force, for example, a force pulling the display panel 10 acts, as shown in FIG. 3C, an angle θ′ (where θ′>θ) between the edge of the base portion BSP and the edge of each connecting portion CNP may increase, the area or shape of a separation area V′ may be changed, and the position of the base portion BSP may also be changed. FIG. 3C is a plan view showing that the display panel 10 is stretched in the first direction (e.g., x direction or −x direction) and the second direction (e.g., y direction or −y direction), and when the above-mentioned external force is applied, each of the base portions BSP may rotate at a certain angle by changing the above-mentioned angle θ′ and increasing the area of the separation area V′, and/or deforming the shape. Intervals between the base portions BSP, for example, a first distance d1′ and a second distance d2′, may vary for each position by the rotation of each of the base portions BSP.

When a force pulling the display panel 10 acts, because stress may be concentrated in the connecting portion CNP connected to the edge of the base portion BSP, the closed curve CL defining the through portion PNP may include a curve to prevent damage to the display panel 10.

Similar to the above, for example, when a force compressing the display panel 10 acts, the angle θ between the edge of the base portion BSP and the edge of each connecting portion CNP may decrease, the area or shape of the separation area V may be changed, and the position of the base portion BSP may also be changed. As described above, stretching and contracting characteristics may be provided to the display panel 10.

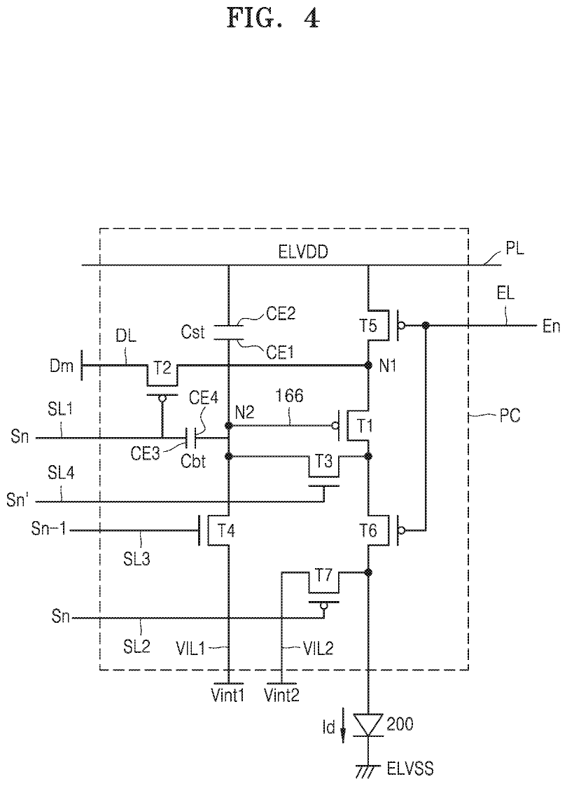

FIG. 4 is an equivalent circuit diagram of one pixel circuit included in a display device according to an embodiment.

Referring to FIG. 4, a pixel circuit PC may include a plurality of thin-film transistors TFT and capacitors. For example, the pixel circuit PC may include first, second, third, fourth, fifth, sixth, and seventh thin-film transistors T1, T2, T3, T4, T5, T6, and T7, a storage capacitor Cst, and a boost capacitor Cst. In addition, the pixel circuit PC may be connected to a plurality of signal lines, first and second initialization voltage lines VIL1 and VIL2, and a power voltage line PL. The signal lines may include a data line DL, a first scan line SL1, a second scan line SL2, a third scan line SL3, a fourth scan line SL4, and an emission control line EL. In another embodiment, at least one of the signal lines, the first and second initialization voltage lines VIL1 and VIL2, and/or the power voltage line PL may be shared by adjacent pixel circuits.

The power voltage line PL may transmit a driving power voltage ELVDD to the first thin-film transistor T1. The first initialization voltage line VIL1 may transmit a first initialization voltage Vint1 for initializing the first thin-film transistor T1 to the pixel circuit PC. The second initialization voltage line VIL2 may transmit a second initialization voltage Vint2 for initializing a light-emitting device 200 to the pixel circuit PC.

For example, in FIG. 4, the third thin-film transistor T3 and the fourth thin-film transistor T4 from among the first, second, third, fourth, fifth, sixth, and seventh thin-film transistors T1, T2, T3, T4, T5, T6, and T7 are implemented as an n-channel MOSFET (NMOS), and the rest are implemented as a p-channel MOSFET (PMOS).

The first thin-film transistor T1 may be connected to the power voltage line PL via the fifth thin-film transistor T5, and may be electrically connected to the light-emitting device 200 via the sixth thin-film transistor T6. The first thin-film transistor T1 serves as a driving thin-film transistor, and may supply a driving current Id to the light-emitting device 200 by receiving a data signal Dm according to a switching operation of the second thin-film transistor T2.

The second thin-film transistor T2 is a switching thin-film transistor, and may be connected to the first scan line SL1 and the data line DL and may be connected to the power voltage line PL via the fifth thin-film transistor T5. The second thin-film transistor T2 may perform a switching operation of transmitting the data signal Dm, which is turned on according to the first scan signal Sn received through the first scan line SL1 and transmitted to the data line DL, to a first node N1.

The third thin-film transistor T3 is a compensation thin-film transistor, and may be connected to the fourth scan line SL4 and may be connected to the light-emitting device 200 via the sixth thin-film transistor T6. The third thin-film transistor T3 may be turned on according to a fourth scan signal Sn′ received through the fourth scan line SL4 to diode-connect the first thin-film transistor T1.

The fourth thin-film transistor T4 is a first initialization thin-film transistor, and may be connected to the third scan line SL3 and the first initialization voltage line VIL1, which are previous scan lines, and may be turned on according to a third scan signal Sn−1, which is a previous scan signal received through the third scan line SL3, to transmit the first initialization voltage Vint1 from the first initialization voltage line VIL1 to a gate electrode of the first thin-film transistor T1 to initialize a voltage of the gate electrode of the first thin-film transistor T1.

The fifth thin-film transistor T5 may be an operation control thin-film transistor, and the sixth thin-film transistor T6 may be an emission control thin-film transistor. The fifth thin-film transistor T5 and the sixth thin-film transistor T6 are connected to the emission control line EL and are turned on at the same time according to an emission control signal En received through the emission control line EL to form a current path so that the driving current Id flows from the power voltage line PL in a direction of the light-emitting device 200.

The seventh thin-film transistor T7 is a second initialization thin-film transistor and is connected to the second scan line SL2 and the second initialization voltage line VIL2, which are the next scan lines, and may be turned on according to a second scan signal Sn+1, which is a next scan signal received through the second scan line SL2, to transmit the second initialization voltage Vint2 from the second initialization voltage line VIL2 to the light-emitting device 200 to initialize the light-emitting device 200. In some embodiments, the seventh thin-film transistor T7 may be omitted.

The storage capacitor Cst may include a first electrode CE1 and a second electrode CE2. The first electrode CE1 may be connected to the gate electrode of the first thin-film transistor T1, and the second electrode CE2 may be connected to the power voltage line PL. The storage capacitor Cst may maintain a voltage applied to the gate electrode of the first thin-film transistor T1 by storing and maintaining a voltage corresponding to a difference between voltages at both ends of the power voltage line PL and the gate electrode of the first thin-film transistor T1

The boost capacitor Cst may include a third electrode CE3 and a fourth electrode CE4. The third electrode CE3 may be connected to the gate electrode of the first scan line SL1 and the second thin-film transistor T2. The fourth electrode CE4 may be connected to the gate electrode of the first thin-film transistor T1 and the first electrode CE1 of the storage capacitor Cst. When the first scan signal Sn of the first scan line SL1 is a voltage for turning off the second thin-film transistor T2, the boost capacitor Cst, which is a boosting capacitor, may increase a voltage of a second node N2 to reduce a voltage (black voltage) representing black.

The light-emitting device 200 includes a pixel electrode and an opposite electrode, and the opposite electrode may receive a common power voltage ELVSS. The light-emitting device 200 receives the driving current Id from the first thin-film transistor T1 and emits light to display an image.

A specific operation of each pixel circuit PC according to an embodiment is as follows.

When the third scan signal Sn−1 is supplied through the third scan line SL3 during a first initialization period, the fourth thin-film transistor T4 is turned on in response to the third scan signal Sn−1, and the first thin-film transistor T1 may be initialized by the first initialization voltage Vint1 supplied from the first initialization voltage line VIL1.

When each of the first scan signal Sn and the fourth scan signal Sn′ is supplied through the first scan line SL1 and the fourth scan line SL4 during a data programming period, the second thin-film transistor T2 and the third thin-film transistor T3 may be turned on in response to the first scan signal Sn and the fourth scan signal Sn′. At this time, the first thin-film transistor T1 may be diode-connected by the turned-on third thin-film transistor T3 and may be biased in the forward direction. In the data signal Dm supplied from the data line DL, a voltage for which a threshold voltage Vth of the first thin-film transistor T1 is compensated may be applied to the first gate electrode G1 of the first thin-film transistor T1. The driving power supply voltage ELVDD and the compensation voltage may be applied to both ends of the storage capacitor Cst, and a charge corresponding to a voltage difference between the both ends may be stored in the storage capacitor Cst.

During a light-emitting period, the fifth thin-film transistor T5 and the sixth thin-film transistor T6 may be turned on by the emission control signal En supplied from the light emission control line EL. The driving current Id may be generated according to a voltage difference between the voltage of the gate electrode of the first thin-film transistor T1 and the driving power supply voltage ELVDD, and the driving current Id may be supplied to the light-emitting device 200 through the sixth thin-film transistor T6.

When the second scan signal Sn+1 is supplied through the second scan line SL2 during the second initialization period, the seventh thin-film transistor T7 is turned on in response to the second scan signal Sn+1, and the light-emitting device 200 is initialized by the second initialization voltage Vint2 supplied from the second initialization voltage line VIL2.

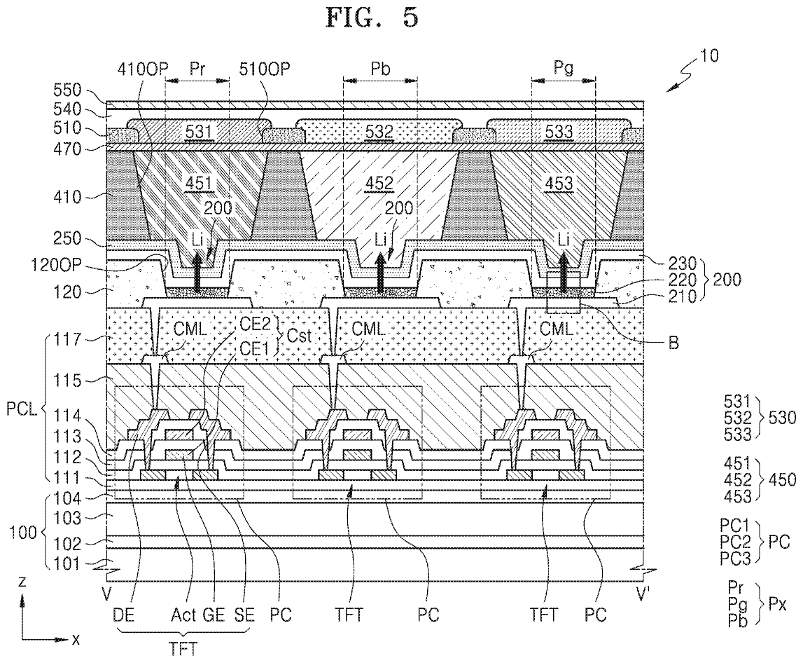

FIG. 5 is a schematic cross-sectional view of a portion of a display panel according to an embodiment, and may correspond to a cross-section of the display panel taken along line V-V of FIG. 3.

Referring to FIG. 5, the display panel 10 may include a substrate 100 having flexible characteristics. In an embodiment, the substrate 100 may include a first base layer 101, a first barrier layer 102, a second base layer 103, and a second barrier layer 104 that are sequentially stacked. The first base layer 101 and the second base layer 103 may include PI, PES, polyarylate, PEI, PEN, PET, PPS, PC, TAC, or/and CAP. The first barrier layer 102 and the second barrier layer 104 may include an inorganic insulating material such as silicon oxide, silicon oxynitride, and/or silicon nitride.

A pixel circuit layer PCL is disposed on the substrate 100. The pixel circuit layer PCL may include the pixel circuit PC including the plurality of thin-film transistors TFT and the storage capacitor Cst. As described above, the pixel circuit PC may further include a boost capacitor Cbt (see FIG. 4). However, for convenience of illustration, FIG. 5 shows a cross-section of one thin-film transistor and the storage capacitor Cst. Further, the pixel circuit layer PCL may include a buffer layer 111 below or/and above components of the pixel circuit PC, a first gate insulating layer 112, a second gate insulating layer 113, an interlayer insulating layer 114, a first planarization insulating layer 115, and a second planarization insulating layer 117.

The buffer layer 111 may reduce or block the penetration of foreign materials, moisture, or external air from a lower portion of the substrate 100 and may provide a flat surface on the substrate 100. The buffer layer 111 may include an inorganic insulating material such as silicon oxide, silicon oxynitride, or silicon nitride, and may have a single layer or multilayer structure including the above-described materials.

The thin-film transistor TFT on the buffer layer 111 may include a semiconductor layer Act, and the semiconductor layer Act may include polysilicon. Alternatively, the semiconductor layer Act may include amorphous silicon, an oxide semiconductor, an organic semiconductor, or the like. The semiconductor layer Act may include a channel area and a drain area and a source area respectively disposed on both sides of the channel area. A gate electrode GE may overlap the channel area.

The gate electrode GE may include a low resistance metal material. The gate electrode GE may include a conductive material including molybdenum (Mo), aluminum (Al), copper (Cu), titanium (Ti), or the like, and may be formed as a single layer or multiple layers including the above-described materials.

The first gate-insulating layer 112 between the semiconductor layer Act and the gate electrode GE may include an inorganic insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

The second gate-insulating layer 113 may be provided to cover the gate electrode GE. Similar to the first gate insulating layer 112, the second gate insulating layer 113 may include an inorganic insulating material such as SiO₂, SiNx, SiON, Al₂O₃, TiO₂, Ta₂O₅, HfO₂, or ZnO₂.

An upper electrode Cst2 of the storage capacitor Cst may be disposed on the second gate-insulating layer 113. The upper electrode Cst2 may overlap the gate electrode GE therebelow. In this case, the gate electrode GE and the upper electrode Cst2 overlapping each other with the second gate insulating layer 113 therebetween may form the storage capacitor Cst. That is, the gate electrode GE may function as a lower electrode Cst1 of the storage capacitor Cst.

As such, the storage capacitor Cst and the thin-film transistor TFT may overlap each other. In some embodiments, the storage capacitor Cst may not overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may be a single layer or multiple layers of the above-described materials.

The interlayer insulating layer 114 may cover the upper electrode Cst2. The interlayer insulating layer 114 includes SiO₂, SiNx, SiON, Al₂O₃, TiO₂, Ta₂O₅, HfO₂, or ZnO₂. The interlayer insulating layer 114 may include a single layer or multiple layers including the above-described inorganic insulating material.

Each of the a drain electrode DE and a source electrode SE may be disposed on the interlayer insulating layer 114. The drain electrode DE and the source electrode SE may be connected to a drain area and a source area through contact holes formed in the insulating layers 112, 113, and 114. The drain electrode DE and the source electrode SE may include a material having good conductivity. The drain electrode DE and the source electrode SE may include a conductive material including Mo, Al, Cu, Ti, and the like, and may be formed as a single layer or multiple layers including the above-described materials. In an embodiment, the drain electrode DE and the source electrode SE may have a multilayer structure of Ti/Al/Ti.

The first planarization insulating layer 115 may cover the drain electrode DE and the source electrode SE. The first planarization insulating layer 115 may include an organic insulation material such as a general commercial polymer such as PMMA or PS, a polymer derivative including a phenolic group, an acrylic polymer, an imide polymer, an aryl ether polymer, an amide polymer, a fluorine-based polymer, a p-xylene-based polymer, a vinyl alcohol polymer, and/or a blend thereof.

A contact metal layer CML may be disposed on the first planarization-insulating layer 115. The contact metal layer CML may include a conductive material including Mo, Al, Cu, Ti, or the like, and may be formed as a single layer or multiple layers including the above-described materials. The contact metal layer CML may be electrically connected to the pixel circuit PC therebelow through a contact hole formed in the first planarization-insulating layer 115.

The second planarization insulating layer 117 may be disposed on the first planarization insulating layer 115 and may cover the contact metal layer CML. The second planarization insulating layer 117 may include the same material as that of the first planarization insulating layer 115, and may include an organic insulation material such as a general commercial polymer such as PMMA or PS, a polymer derivative including a phenolic group, an acrylic polymer, an imide polymer, an aryl ether polymer, an amide polymer, a fluorine-based polymer, a p-xylene-based polymer, a vinyl alcohol polymer, and/or a blend thereof.

The light-emitting device 200 may be disposed on the second planarization-insulating layer 117. The light-emitting device 200 may include a stacked structure of a pixel electrode 210, a light-emitting layer 220, and an opposite electrode 230. According to an embodiment, the light-emitting device 200 may be an inorganic light-emitting device including an inorganic semiconductor. The light-emitting device 200 may emit light through a light-emitting area, and the light-emitting area of the light-emitting device 200 may correspond to the pixel PX.

The pixel electrode 210 may be disposed on the second planarization-insulating layer 117. The pixel electrode 210 may be connected to the contact metal layer CML through a contact hole formed in the second planarization insulating layer 117, and may be electrically connected to the thin-film transistor TFT of the pixel circuit PC through the contact metal layer CML. The pixel electrode 210 includes a conductive material, and may include Al, gallium (Ga), or a compound thereof. The pixel electrode 210 may have a single layer or multilayer structure.

A pixel-defining layer 120 may be disposed on the pixel electrode 210. An opening 1200P covering an edge of the pixel electrode 210 and overlapping a central portion of the pixel electrode 210 is defined in the pixel-defining layer 120. The pixel-defining layer 120 may prevent an arc or the like from occurring at the edge of the pixel electrode 210 by increasing a distance between the edge of the pixel electrode 210 and the opposite electrode 230 above the pixel electrode 210. The pixel-defining layer 120 may include an organic insulating material such as PI, polyamide, acrylic resin, benzocyclobutene (BCB), hexamethyldisiloxane (HMDSO), and phenolic resin, and may be formed by spin coating.

The opposite electrode 230 is disposed above the pixel electrode 210 and may overlap the pixel electrode 210. The opposite electrode 230 may include a conductive material having a low work function. For example, the opposite electrode 230 may include a transparent conductive layer, and may include, for example, indium tin oxide (ITO), indium zinc oxide (IZO), zinc oxide (ZnO), indium oxide (In₂O₃), indium gallium oxide (IGO), or aluminum zinc oxide (AZO).

The opposite electrode 230 may be integrally formed to cover the plurality of pixels PX. For example, the opposite electrode 230 is integrally formed to cover the red, blue, and green subpixels Pr, Pg, and Pb, and may entirely cover the display area DA (see FIG. 1) of the display panel 10.

The light-emitting layer 220 is interposed between the pixel electrode 210 and the opposite electrode 230 and may be disposed to correspond to the pixel electrode 210. For example, the light-emitting layer 220 may be integrally formed over the plurality of pixel electrodes 210. As another example, the light-emitting layer 220 may be patterned to correspond to each pixel electrode 210, and in this case, the light-emitting layer 220 may be disposed in the opening 1200P of the pixel definition layer 120.

According to an embodiment, the light-emitting layer 220 may include a semiconductor material, for example, an inorganic semiconductor material. In an embodiment, the semiconductor material of the light-emitting layer 220 may include polycrystalline aluminum nitride (AlN) doped with silicon (Si) or polycrystalline gallium nitride (GaN) doped with Si. In an embodiment, a thickness of the light-emitting layer 220 may be about 100 Å or less.

In an embodiment, the light-emitting layer 220 may emit light of a specific wavelength band, for example, may emit light of a wavelength belonging to about 200 nm to about 220 nm.

As a comparative example, when a display panel includes an organic light-emitting diode having a light-emitting layer including an organic material, an encapsulation layer capable of covering and protecting the organic light-emitting diode is essential because the organic light-emitting diode may be easily damaged by moisture or oxygen from the outside. This encapsulation layer includes not only an inorganic encapsulation layer but also an organic encapsulation layer. When only an inorganic encapsulation layer is provided, because the inorganic encapsulation layer is relatively thin, it is vulnerable to formation of irregularities or seams caused by foreign substances that may be introduced during a manufacturing process, and external moisture or oxygen may be introduced to the organic light-emitting diode through the irregularities or seams, resulting in deterioration of the organic light-emitting diode.

However, in the process of forming the organic encapsulation layer, when a monomer constituting the organic encapsulation layer flows into the through portion PNP (see FIG. 3B) of the substrate 100, the contraction and stretching characteristics of the substrate 100 may be greatly inhibited. In addition, when a structure such as a barrier or a dam is formed on an outer edge of the base portion BSP (see FIG. 3B) of the substrate 100 to control a flow of the monomer or when a contact structure between inorganic encapsulation layers arranged above and below the organic encapsulation layer is formed, an area in which the pixels PX may be disposed in the base portion BSP is reduced. For this reason, restrictions may arise in improving the resolution, aperture ratio, or brightness of the display panel 10.

In order to eliminate the above-described problems or design restrictions, the display panel 10 according to an embodiment may employ the light-emitting device 200 including an inorganic semiconductor material instead of an organic light-emitting diode. By employing the light-emitting device 200, the display panel 10 does not require an organic encapsulation layer. Accordingly, the flexibility, resolution, and brightness of the display panel 10 may be improved. Furthermore, because the light-emitting device 200 has a stacked structure similar to that of the organic light-emitting diode and has a relatively simple structure, the light-emitting device 200 may be easily manufactured.

The light-emitting device 200 may emit light having a wavelength out of a wavelength band of visible light, and, as described above, may emit light having a wavelength ranging from, for example, about 200 nm to about 220 nm. Thus, according to an embodiment, the display panel 10 may include a light conversion layer 450 that converts light emitted from the light-emitting device 200 into visible light. That is, the light emitted from the light-emitting device 200 may be incident on the light conversion layer 450 as incident light Li, and the incident light Li may be converted into visible light in the light conversion layer 450. The light conversion layer 450 may be disposed on the opposite electrode 230 and may overlap the light-emitting layer 220.

In more detail, the light conversion layer 450 may be disposed in an opening 4100P of a light shielding wall portion 410. The light shielding wall portion 410 may be on the opposite electrode 230 and may overlap the pixel-defining layer 120. The opening 4100P of the light shielding wall portion 410 may correspond to the light-emitting device 200.

The light shielding wall portion 410 may be of various colors including black, white, red, purple, blue, and the like. The light shielding wall portion 410 may include a colored pigment or dye. In addition/alternatively, the light shielding wall portion 410 may include a light shielding material, and the light shielding material may include an opaque inorganic insulating material including a metal oxide such as titanium oxide (TiO₂), chromium oxide (Cr₂O₃), or molybdenum oxide (MoO₃), or an opaque organic insulating material such as a black resin. As another example, the light shielding wall portion 410 may include an organic insulating material such as a white resin.

The light shielding wall portion 410, as described later below, may prevent a color mixture from occurring between lights converted by a first light conversion layer 451, a second light conversion layer 452, and a third light conversion layer 453 adjacent to each other.

The light conversion layer 450 may include the first light conversion layer 451, the second light conversion layer 452, and a third light conversion layer 453. Each of the first light conversion layer 451, the second light conversion layer 452, and the third light conversion layer 453 may be disposed in the opening 4100P of the light shielding wall portion 410, and may correspond to one light-emitting device 200. The first light conversion layer 451, the second light conversion layer 452, and the third light conversion layer 453 may be spaced apart from each other at a certain distance, and the light shielding wall portion 410 may be disposed therebetween.

The first light conversion layer 451, the second light conversion layer 452, and the third light conversion layer 453 may convert the incident light Li generated from the light-emitting device 200 into visible light having a specific color. Light converted by the first light conversion layer 451, the second light conversion layer 452, or the third light conversion layer 453 is visible light and may be one of red light, green light, and blue light. For example, light converted by the first light conversion layer 451 may be red light having a wavelength band of 580 nm or more and less than 750 nm, light converted by the second light conversion layer 452 may be blue light having a wavelength band of 400 nm or more and less than 495 nm, and light converted by the third light conversion layer 453 may be green light having a wavelength band of 495 nm or more and less than 580 nm.

A first capping layer 250 may be disposed between the opposite electrode 230 and the light conversion layer 450. The first capping layer 250 may cover the opposite electrode 230. In addition, the first capping layer 250 may protect a lower portion of the light conversion layer 450. The first capping layer 250 may include, for example, an inorganic insulating material such as silicon nitride, silicon oxide, or silicon oxynitride.

According to an embodiment, because the light-emitting device 200 of the display panel 10 includes the light-emitting layer 220 including an inorganic semiconductor material, an organic encapsulation layer may not be provided between the light-emitting device 200 and the light conversion layer 450. Accordingly, in an embodiment, the first capping layer 250 may be in direct contact with not only the opposite electrode 230, but also the light conversion layer 450. However, the disclosure is not limited thereto, and another inorganic layer may be disposed above and/or below the first capping layer 250. In this case, the first capping layer 250 may not directly contact the opposite electrode 230 and/or the light conversion layer 450.

A second capping layer 470 may be disposed on the light conversion layer 450. The second capping layer 470 may be formed to cover the light conversion layer 450. The second capping layer 470 may protect an upper portion of the light conversion layer 450. The second capping layer 470 may include the same material as that of the first capping layer 250 described above, and may include an inorganic insulating material such as silicon nitride, silicon oxide, or silicon oxynitride.

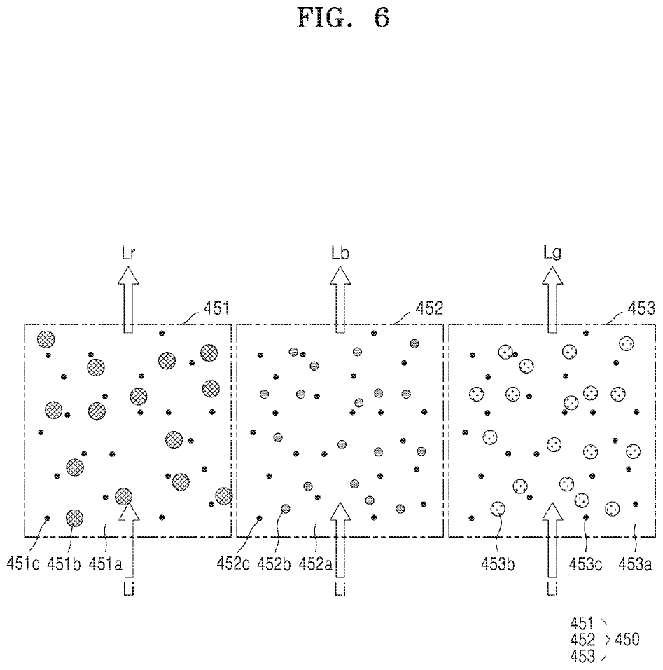

The light conversion layer 450 may include quantum dots as will be described later with reference to FIG. 6, and because the quantum dots are composed of nanoparticles, they may deteriorate by reacting with moisture and oxygen. Therefore, the first capping layer 250 and the second capping layer 470 may cover the light conversion layer 450 at the upper and lower portions of the light conversion layer 450 so that moisture, oxygen, and the like do not flow into the quantum dots in the light conversion layer 450.

A light shielding layer 510 may be disposed on the second capping layer 470. The light shielding layer 510 may include an opening 5100P overlapping the opening 4100P of the light shielding wall portion 410. The light shielding layer 510 may include a light shielding material. The light shielding material may include an opaque inorganic insulating material including a metal oxide such as TiO₂, Cr₂O₃, or MoO₃, or an opaque organic insulating material such as a black resin. The light shielding layer 510 may prevent light from being emitted to the outside to an area other than the light-emitting area, thereby preventing a light leakage phenomenon from occurring in the display panel 10.

A color filter layer 530 may be disposed on the second capping layer 470 and may overlap the light conversion layer 450. The color filter layer 530 may be disposed in the opening 5100P of the light shielding layer 510. In some embodiments, a portion of the color filter layer 530 may be disposed on the light shielding layer 510.

In an embodiment, the color filter layer 530 may include first, second, and third color filter layers 531, 532, and 533 corresponding to the first, second, and third light conversion layers 451, 452, and 453 of the light conversion layer 450, respectively. The first, second, and third color filter layers 531, 532, and 533 may be organic patterns including dyes or pigments. The first, second, and third color filter layers 531, 532, and 533 may include pigments or dyes of different colors to selectively transmit only light of the corresponding color, respectively. For example, the first color filter layer 531 may selectively transmit only red light including a red pigment or dye, the second color filter layer 532 may selectively transmit only blue light including a blue pigment or dye, and the third color filter layer 533 may selectively transmit only green light including a green pigment or dye.

In some embodiments, when considering the amount of each color light emitted from the display panel 10, a thickness of the second color filter layer 532 may be greater than thicknesses of the first color filter layer 531 and the third color filter layer 533.

As a further example, the light shielding layer 510 may include the same material as that of the second color filter layer 532 and may be formed by the same process. The light shielding layer 510 may not form the opening 5100P at a position corresponding to the second light conversion layer 452, and a portion of the light shielding layer 510 may function as the second color filter layer 532.

The incident light Li may be converted to visible light through the light conversion layer 450 and then proceed to the color filter layer 530. For example, the incident light Li may be converted into red light through the first light conversion layer 451 and then proceed to the first color filter layer 531. Another incident light Li may be converted to blue light through the second light conversion layer 452 and then proceed to the second color filter layer 532. The other incident light Li may be converted to green light through the third light conversion layer 453 and then proceed to the third color filter layer 533. Lights passing through the first, second, and third color filter layers 531, 532, and 533 may be emitted to the outside. A color image is displayed by red, blue, and green lights emitted to the outside. A light-emitting area from which red light is emitted is defined as the red subpixel Pr, a light-emitting area from which green light is emitted is defined as the green subpixel Pg, and a light-emitting area from which blue light is emitted may be defined as the blue subpixel Pb.

A filler 540 may be disposed on the light shielding layer 510 and may cover the color filter layer 530. The filler 540 may buffer against external pressure and the like, and may provide a flat surface on an upper surface. The filler 540 may include organic materials such as acrylic resin, epoxy resin, polyimide, and polyethylene.

A third capping layer 550 may be disposed on the filler 540. The third capping layer 550 may include the same material as that of the first capping layer 250 and the second capping layer 470, and may include an inorganic insulating material such as silicon nitride, silicon oxide, or silicon oxynitride.

FIG. 6 is a cross-sectional view of a portion of a light conversion layer of a display panel according to an embodiment.

Referring to FIG. 6, the light conversion layer 450 of the display panel 10 (of FIG. 5) may include the first, second, and third light conversion layers 451, 452, and 453. In an embodiment, the incident light Li may be light having a wavelength belonging to about 200 nm to about 220 nm, and may be incident on the light conversion layer 450.

For example, the first light conversion layer 451 may convert the incident light Li into red light Lr. To this end, the first light conversion layer 451 may include a first photosensitive polymer 451a in which first quantum dots 451b are dispersed.

The first photosensitive polymer 451a is not particularly limited as long as it is a material having excellent dispersion characteristics and light transmittance, and may include, for example, an acrylic resin, an imide resin, or an epoxy resin.

The first quantum dots 451b are excited by the incident light Li to emit the red light Lr having a wavelength (e.g., a wavelength of 580 nm or more and less than 750 nm) longer than that of the incident light Li in an isotropic manner. In the present specification, a quantum dot refers to a crystal of a semiconductor compound, and may include any material capable of emitting light in various wavelength bands according to a size of the crystal.

The first quantum dots 451b may be synthesized by a wet chemical process, an organometallic chemical vapor deposition process, a molecular beam epitaxy process, or a similar process. The wet chemical process is a method of growing quantum dot particle crystals after mixing an organic solvent and a precursor material. In the wet chemical process, when the crystal grows, the organic solvent naturally acts as a dispersant coordinated on a surface of the quantum dot crystals and controls growth of the crystals. Therefore, the wet chemical process is easier than a vapor deposition method such as metal organic chemical vapor deposition (MOCVD) or molecular beam epitaxy (MBE), and through a low-cost process, the growth of quantum dot particles may be controlled.

The first quantum dots 451b may include a Group III-VI semiconductor compound, a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

Examples of the Group III-VI semiconductor compound may include a two-element compound such as In₂S₃, a three-element compound such as AgInS, AgInS₂, CuInS, and CuInS₂, or any combination thereof.

Examples of the Group II-VI semiconductor compound may include a two-element compound such as CdS, CdSe, CdTe, ZnS, ZnSe, ZnTe, ZnO, HgS, HgSe, HgTe, MgSe, MgS, and the like, a three-element compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and the like, a four-element compound such as CdZnSeS, CdZnSeTe, CdZnSTe, CdHgSeS, CdHgSeTe, CdHgSTe, HgZnSeS, HgZnSeTe, HgZnSTe, and the like, or any combination thereof.

Examples of the Group III-V semiconductor compound may include a two-element compound such as GaN, GaP, GaAs, GaSb, AlN, AlP, AlAs, AlSb, InN, InP, InAs, InSb, and the like, a three-element compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, and the like, a four-element compound such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and the like, or any combination thereof. Meanwhile, the Group III-V semiconductor compound may further include a Group II element. Examples of the Group III-V semiconductor compound further including a Group II element may include InZnP, InGaZnP, InAlZnP, or the like.

Examples of the Group III-VI semiconductor compound may include a two-element compound such as GaS, GaSe, Ga₂Se₃, GaTe, InS, InSe, In₂Se₃, InTe, and the like, a three-element compound such as InGaS₃ and InGaSe₃, or any combination thereof.

Examples of the Group I-III-VI semiconductor compound may include a three-element compound such as AgInS, AgInS₂, CuInS, CuInS₂, CuGaO₂, AgGaO₂, AgAlO₂, and the like, or any combination thereof.

Examples of the Group IV-VI semiconductor compound may include a two-element compound such as SnS, SnSe, SnTe, PbS, PbSe, PbTe, and the like, a three-element compound such as SnSeS, SnSeTe, SnSTe, PbSeS, PbSeTe, PbSTe, SnPbS, SnPbSe, SnPbTe, and the like, a four-element compound such as SnPbSSe, SnPbSeTe, SnPbSTe, and the like, or any combination thereof.

The Group IV element or compound may include a single-element compound such as Si or Ge, a two-element compound such as SiC and SiGe, or any combination thereof.

Each of elements included in a multi-element compound such as a two-element compound, a three-element compound, and a four-element compound may be in a particle in a uniform concentration or in a non-uniform concentration.

Meanwhile, the first quantum dots 451b may have a single structure or a core-shell dual structure in which concentrations of elements included in a corresponding quantum dot are uniform. For example, a material included in the core and a material included in the shell may be different from each other.

The shell may serve as a protective layer for maintaining semiconductor properties by preventing chemical modification of the core and/or a charging layer for imparting electrophoretic properties to quantum dots. The shell may be a single layer or multiple layers. An interface between a core and a shell may have a concentration gradient. In this case, a concentration of an element in the shell decreases towards a center of the shell.

Examples of the shell may include a metal or non-metal oxide, a semiconductor compound, or a combination thereof. Examples of the metal or non-metal oxide may include a two-element compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and the like, a three-element compound such as MgAl₂O₄, CoFe₂O₄, NiFe₂O₄, CoMn₂O₄, and the like, or any combination thereof. Examples of the semiconductor compound may include, as described herein, the Group III-VI semiconductor compound, the Group II-VI semiconductor compounds, the Group III-V semiconductor compound, the Group III-VI semiconductor compound, the Group I-III-VI semiconductor compound, the Group IV-VI semiconductor compound, or any combination thereof. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

The first quantum dots 451b may have a full width of half maximum (FWHM) of an emission wavelength spectrum of about 45 nm or less, specifically about 40 nm or less, and more specifically about 30 nm or less, and in this range, color purity and color reproducibility may be improved. In addition, because light emitted through the first quantum dots 451b is emitted in all directions, a wide viewing angle may be improved.

In addition, the shape of the first quantum dots 451b may be specifically spherical, pyramidal, multi-arm, or cubic nanoparticles, nanotubes, nanowires, nanofibers, nanoplatelet particles, or the like. First scattering particles 451c may be further dispersed in the first photosensitive polymer 451a. The first scattering particles 451c scatter blue incident light Li not absorbed by the first quantum dots 451b so that more first quantum dots 451b are excited, thereby increasing the color conversion efficiency of the first light conversion layer 451. In addition, the first scattering particles 451c may scatter light in various directions regardless of an incident angle without substantially converting a wavelength of incident light. Through this, side visibility may be improved.

The first scattering particles 451c may be particles having a refractive index different from that of the first photosensitive polymer 451a, such as light scattering particles. The first scattering particles 451c are not particularly limited as long as they form an optical interface with the first photosensitive polymer 451a to partially scatter transmitted light, but may be, for example, metal oxide particles or organic particles. Examples of the metal oxide particles may include TiO₂, zirconium oxide (ZrO₂), Al₂O₃, indium oxide (In₂O₃), ZnO, or tin oxide (SnO₂), and examples of the organic particles may include an acrylic resin or a urethane resin.

The second light conversion layer 452 may convert incident light Li into blue light Lb. The second light conversion layer 452 may include a second photosensitive polymer 452a in which second quantum dots 452b are dispersed, and second scattering particles 452c are dispersed together with the second quantum dots 452b in the second photosensitive polymer 452a, thereby increasing color conversion efficiency of the second light conversion layer 452.

The second photosensitive polymer 452a may include the same material as that of the first photosensitive polymer 451a, and the second scattering particles 452c may include the same material as that the first scattering particles 451c.

The second quantum dots 452b may include the same material as that of the first quantum dots 451b and may have the same shape. However, the size of the second quantum dots 452b may be less than the size of the first quantum dots 451b. This is to allow the second quantum dots 452b to emit light having a wavelength band different from that of the first quantum dots 451b. In more detail, an energy band gap may be adjusted by adjusting the size of a quantum dot, and thus, light in various wavelength bands may be obtained. The second quantum dots 452b may have a size less than that of the first quantum dots 451b, whereby the second quantum dots 452b are excited by the incident light Li to emit the blue light Lb having a wavelength (e.g., a wavelength of 400 nm or more and less than 495 nm) greater than a wavelength of the incident light Li but less than a wavelength of the red light Lr in an isotropic manner.

The third light conversion layer 453 may convert the incident light Li into green light Lg. The third light conversion layer 453 may include a third photosensitive polymer 453a in which third quantum dots 453b are dispersed, and third scattering particles 453c are dispersed together with the third quantum dots 453b in the third photosensitive polymer 453a, thereby increasing color conversion efficiency of the third light conversion layer 453.

The third photosensitive polymer 453a may include the same material as that of the first photosensitive polymer 451a, and the third scattering particles 453c may include the same material as that the first scattering particles 451c.

The third quantum dots 453b may include the same material as that of the first quantum dots 451b and may have the same shape. However, sizes of the third quantum dots 453b may be less than sizes of the first quantum dots 451b but greater than sizes of the second quantum dots 452b. This is to allow the third quantum dots 453b to emit light having a wavelength band different from that of the first quantum dots 451b and the second quantum dots 452b. In more detail, an energy band gap may be adjusted by adjusting the size of a quantum dot, and thus, light in various wavelength bands may be obtained. The third quantum dots 453b may have a size less than that of the first quantum dots 451b, whereby the third quantum dots 453b are excited by the incident light Li to emit green light Lg having a wavelength (e.g., a wavelength of 400 nm or more and less than 495 nm) greater than wavelengths of the incident light Li and blue light but less than that of the red light Lr in an isotropic manner.

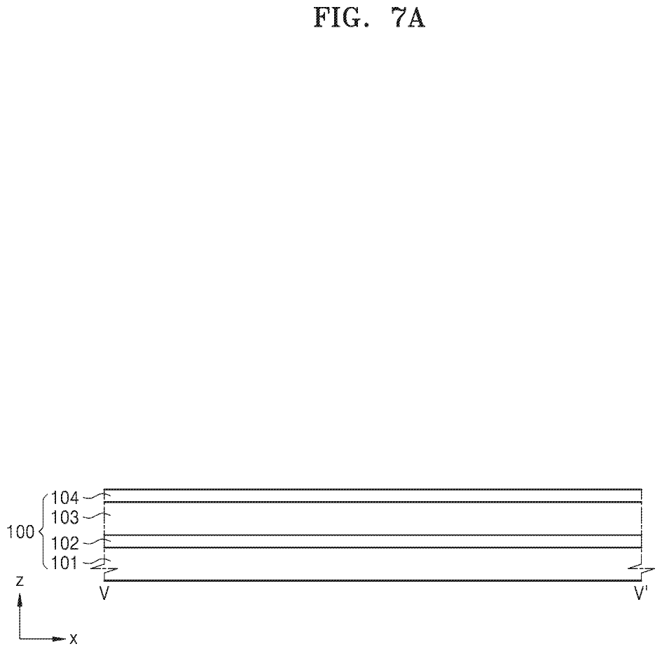

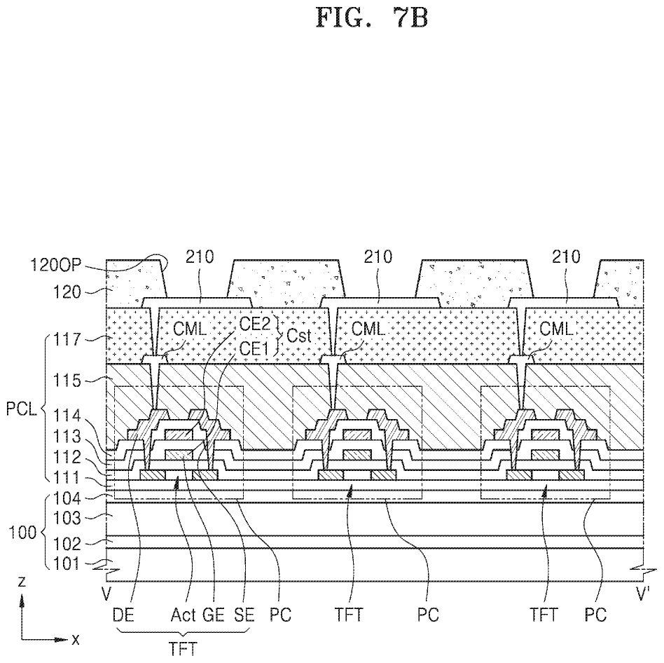

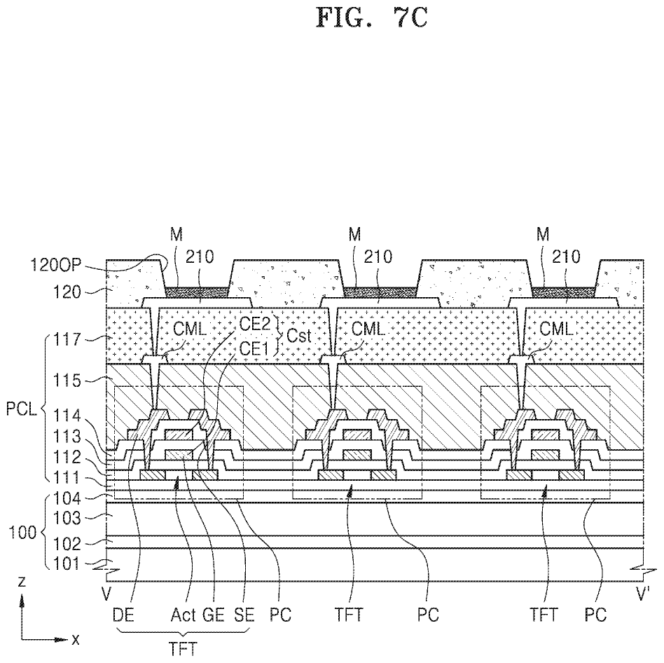

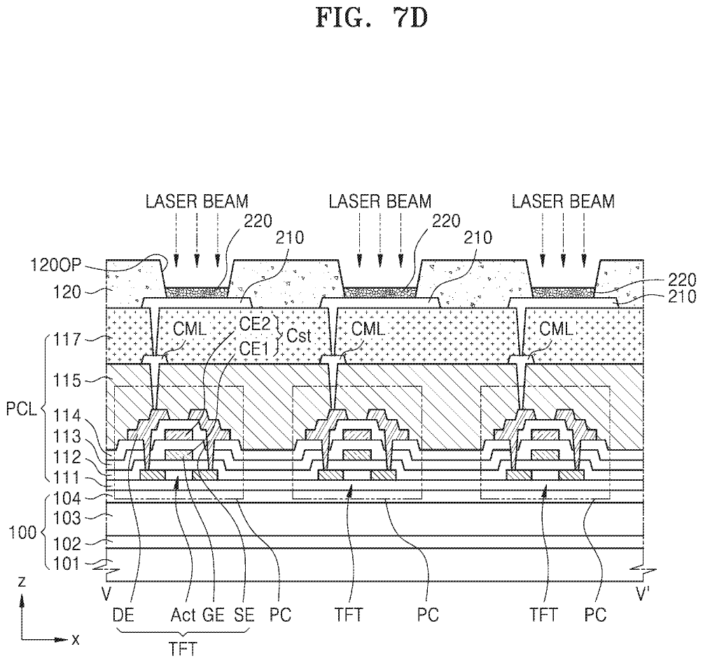

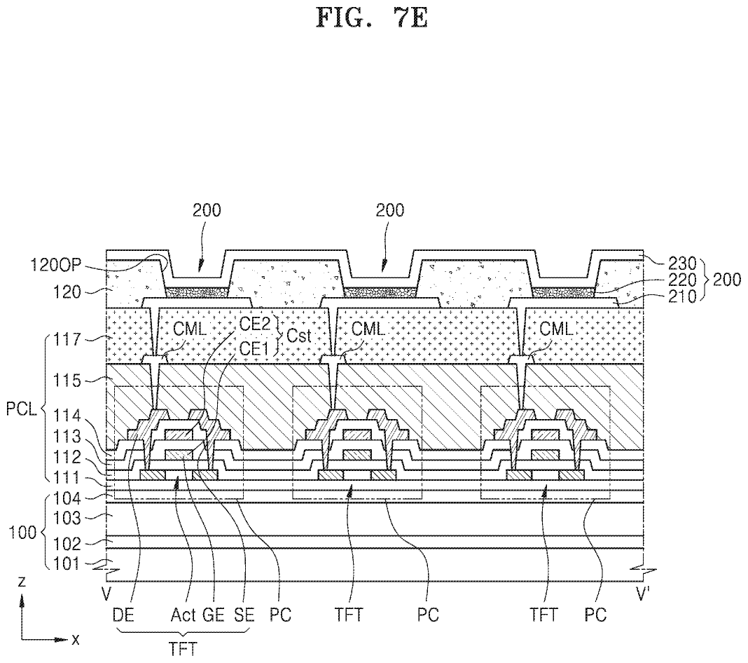

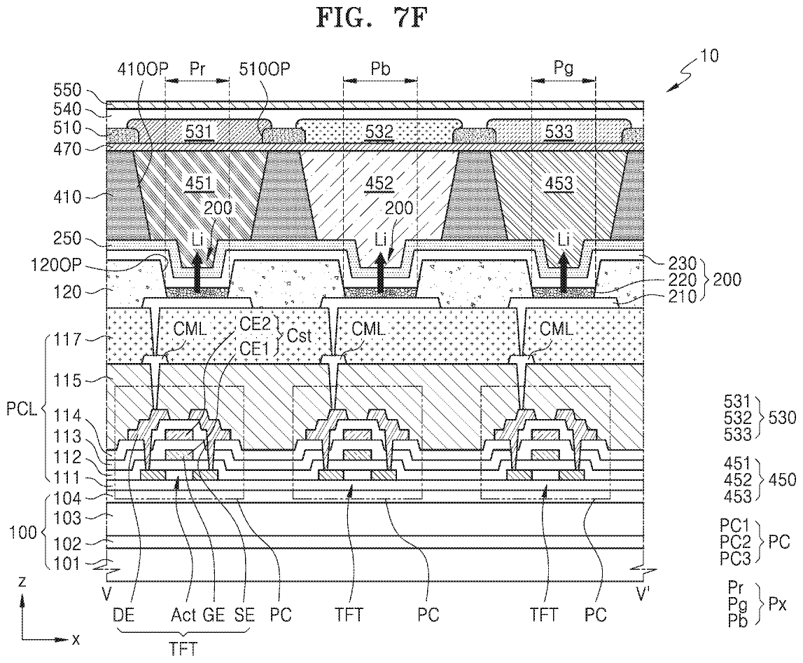

FIGS. 7A, 7B, 7C, 7D, 7E, and 7F are cross-sectional views illustrating a method of manufacturing a display panel according to an embodiment. The same reference numerals are assigned to the same components as those described with reference to FIG. 5, and redundant descriptions thereof will be omitted.

Referring to FIG. 7A, first, the substrate 100 may be prepared. The substrate 100 may include the plurality of through portions PNP (see FIG. 3B) and the plurality of base portions BSP (see FIG. 3B) spaced apart from each other by the plurality of through portions PNP.

The plurality of through portions PNP may be formed by removing an area of the substrate 100 by an etching method. As another example, when the substrate 100 is manufactured, the plurality of through portions PNP may be provided. Examples of a process in which the through portions PNP are formed in components of the substrate 100 may vary, and there is no limitation on a manufacturing method thereof.

Referring to FIG. 7B, the pixel circuit layer PCL may be formed on the substrate 100. As described above, the pixel circuit layer PCL may include the pixel circuit PC, the buffer layer 111 below or/and above components of the pixel circuit PC, the first gate insulating layer 112, the second gate insulating layer 113, the interlayer insulating layer 114, the first planarization insulating layer 115, and the second planarization insulating layer 117.

A deposition process, a photolithography process, an etching process, etc. may be used to form the pixel circuit layer PCL. For example, to form a layer including an inorganic insulating material, a vapor deposition method such as chemical vapor deposition (CVD), thermochemical vapor deposition (TCVD), and plasma enhanced chemical vapor deposition (PECVD) may be used, and to form a layer including a conductive material such as a metal, sputtering, e-beam evaporation, or the like may be used. In addition, layers may be patterned as needed using a photolithography process and an etching process.

The pixel electrode 210 may be formed on the second planarization-insulating layer 117 of the pixel circuit layer PCL on the substrate 100. In an embodiment, the pixel electrode 210 may include Al, Ga, or a compound thereof. For example, after a preliminary pixel electrode layer including Al, Ga, or a compound thereof is formed on the second planarization-insulating layer 117 through sputtering, the pixel electrode 210 may be formed by patterning the preliminary pixel electrode layer using a photolithography process and an etching process.

After the pixel electrode 210 is formed, the pixel-defining layer 120 may be formed. For example, after a preliminary pixel definition film is formed through chemical vapor deposition (CVD), the pixel-defining layer 120 may be formed by forming the opening 1200P in the pixel-defining layer 120 using a photolithography process and an etching process.

Referring to FIG. 7C, in order to form the light-emitting layer 220 on the pixel electrode 210, first, a material layer M including SiNx may be formed on the pixel electrode 210. The material layer M may be formed to correspond to the pixel electrode 210. To form the material layer M, for example, CVD may be used.

Although FIG. 7C shows that, as an embodiment, the material layer M is formed in the opening 1200P of the pixel definition layer 120 so that one material layer M is formed so as to correspond to only one pixel electrode 210. However, the disclosure is not limited thereto. In another embodiment, the material layer M may be formed to correspond to several pixel electrodes 210, and in this case, a portion of the material layer M may be on an upper surface of the pixel-defining layer 120.

Referring to FIG. 7D, a laser beam may be irradiated on the material layer M, and the light-emitting layer 220 may be formed through this. In an embodiment, the type of laser beam used may be an excimer laser. For example, the excimer laser may have a short wavelength of 308 nm.

A portion of the laser beam irradiated to the material layer M may be absorbed by the material layer M, and the remaining portion may reach the pixel electrode 210 through a lower surface of the material layer M. The pixel electrode 210 may also absorb a portion of the laser beam. The laser beam absorbed by the material layer M and the pixel electrode 210 may be converted into thermal energy. As a portion of the material layer M and the pixel electrode 210 is melted and recrystallized by the thermal energy, the light-emitting layer 220 may be formed. The light-emitting layer 220 formed as described above may include a polycrystalline semiconductor material. The polycrystalline semiconductor material may include polycrystalline AlN doped with Si or polycrystalline GaN doped with Si.

In order to form the light-emitting layer 220 according to an embodiment, a laser beam needs to be able to reach the pixel electrode 210 through the lower surface of the material layer M. To this end, the material layer M may have a relatively thin thickness. In an embodiment, when an excimer laser having a short wavelength of 308 nm is used, the thickness of the material layer M may be about 100 Å or less. This is because when the thickness of the material layer M including silicon exceeds about 100 Å, it is difficult for the excimer laser to pass through the material layer M.

Meanwhile, a laser beam may be irradiated in a −z direction, and in this case, a process of inverting the substrate 100 may be selectively added.

Referring to FIG. 7E, the opposite electrode 230 may be formed on the light-emitting layer 220. A deposition method may be used to form the opposite electrode 230.

Referring to FIG. 7F, the first capping layer 250 may be formed on the opposite electrode 230. The first capping layer 250 may be formed by, for example, CVD, TCVD, or PECVD.

The light shielding wall portion 410 having the opening 4100P corresponding to the light-emitting layer 220 may be formed on the first capping layer 250. In an embodiment, the light conversion layer 450 overlapping the light-emitting layer 220 may be formed in the opening 4100P of the light shielding wall portion 410. At this time, the light conversion layer 450 may be disposed on the first capping layer 250, and the first capping layer 250 may contact the opposite electrode 230 and the light conversion layer 450, respectively.

Thereafter, the second capping layer 470, the light shielding layer 510, the color filter layer 530, the filler 540, and the third capping layer 550 may be sequentially formed. Through this, the display panel 10 according to an embodiment may be manufactured.

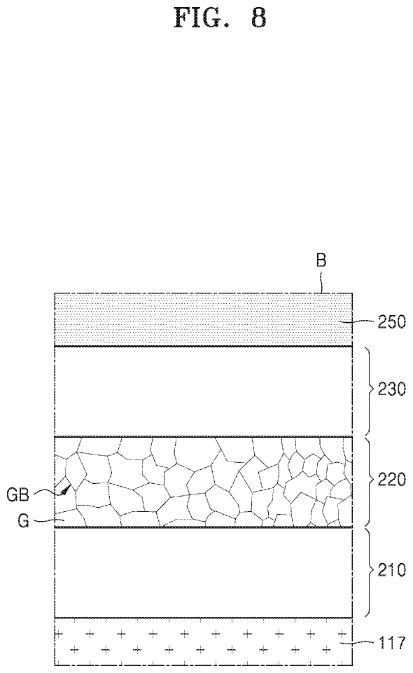

FIG. 8 is a cross-sectional view schematically illustrating a portion of a display panel according to an example embodiment, and may correspond to area B of FIG. 5. The same reference numerals are assigned to the same components as those described with reference to FIG. 5, and redundant descriptions thereof will be omitted.

Referring to FIG. 8, the light-emitting layer 220 of the light-emitting device 200 may include a semiconductor material including a grain boundary GB. As described above, the light-emitting layer 220 formed through recrystallization may include a polycrystalline semiconductor material, and may include grains G that are not grown into a single crystal and grain boundaries GB between the grains G. Because a growth direction of the grain G may be random, the grain boundaries GB may also be formed randomly.

In an embodiment, the grain G of the light-emitting layer 220 may include AlN doped with silicon or GaN doped with silicon, wherein the doping may be n-type doping. Accordingly, the grain G of the light-emitting layer 220 may be in a state of being rich in electrons.

A dangling bond may be formed on the grain boundary GB of the light-emitting layer 220. That is, atoms in the grain G are bonded in all directions, but atoms around the grain boundary GB may be in a state in which some bonds are broken. The dangling bond may act as an electron-hole recombination site.

In more detail, the dangling bond may function as a hole probabilistically. When a constant voltage is applied to the pixel electrode 210 and the opposite electrode 230, a free electron from n-type doped aluminum nitride or gallium nitride may flow through the light-emitting layer 220 and recombine with a hole in the dangling bond of the grain boundary GB. That is, the dangling bond may serve as a multi-quantum well (MQVV) structure. Energy resulting from recombination of holes and electrons is converted into light energy, and thus light may be emitted.

By this principle, the light-emitting layer 220 may include an area in which electrons and holes are recombined, may change to a low energy level as electrons and holes recombine, and may emit light having a wavelength corresponding thereto. In an embodiment, a wavelength of light emitted from the light-emitting layer 220 may range from about 200 nm to about 220 nm.

In another embodiment, the light-emitting layer 220 may include p-type AlN or GaN doped with Mg. Because the dangling bond may also provide electrons, even in this case, the light-emitting layer 220 may include an area in which electrons and holes are recombined.

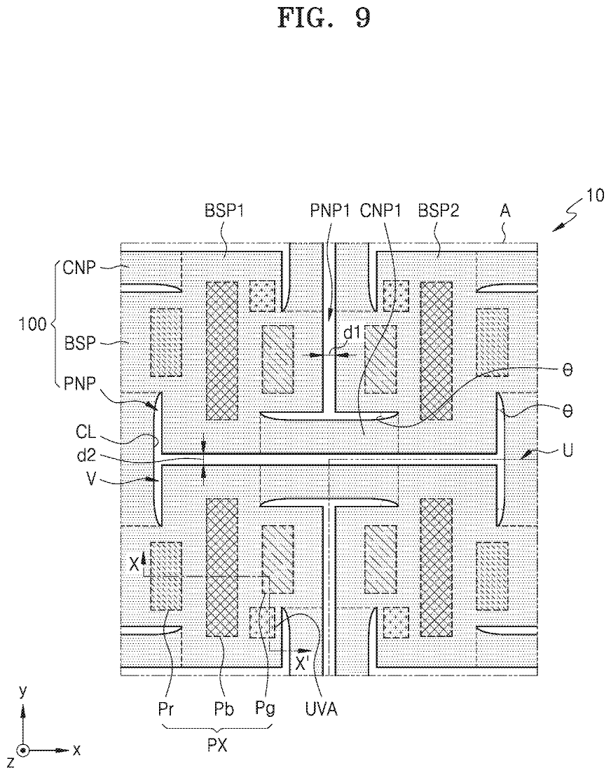

FIG. 9 is an enlarged plan view of a portion of a display panel according to another embodiment. The same contents as those previously described with reference to FIG. 3B will be omitted, and a description will be made focusing on differences hereinafter.

Referring to FIG. 9, the display panel 10 may further include an ultraviolet area UVA. The ultraviolet area UVA may overlap the base portion BSP of the substrate 100 of the display panel 10. The ultraviolet area UVA may be an area in which light (hereinafter referred to as ultraviolet rays) having a wavelength belonging to about 200 nm to about 220 nm is emitted from the display panel 10.

In an embodiment, the ultraviolet area UVA may have an area less than each of the red subpixel Pr, the green subpixel Pg, and the blue subpixel Pb. The area refers to an area on a plane when viewed in a direction perpendicular to one surface of the substrate 100.

Whether or not ultraviolet rays are emitted from the ultraviolet area UVA may be determined independently from whether or not visible light is emitted from the pixel PX. For example, in an image display mode of the display panel 10, visible light may be emitted from the pixel PX, but ultraviolet light may not be emitted from the ultraviolet area UVA. In a specific function mode of the display panel 10, ultraviolet rays may be emitted from the ultraviolet area UVA regardless of whether visible light is emitted.

The display device 1 (see FIG. 1) including the display panel 10 may have a function of sterilizing and disinfecting using ultraviolet rays in addition to a function of displaying an image.

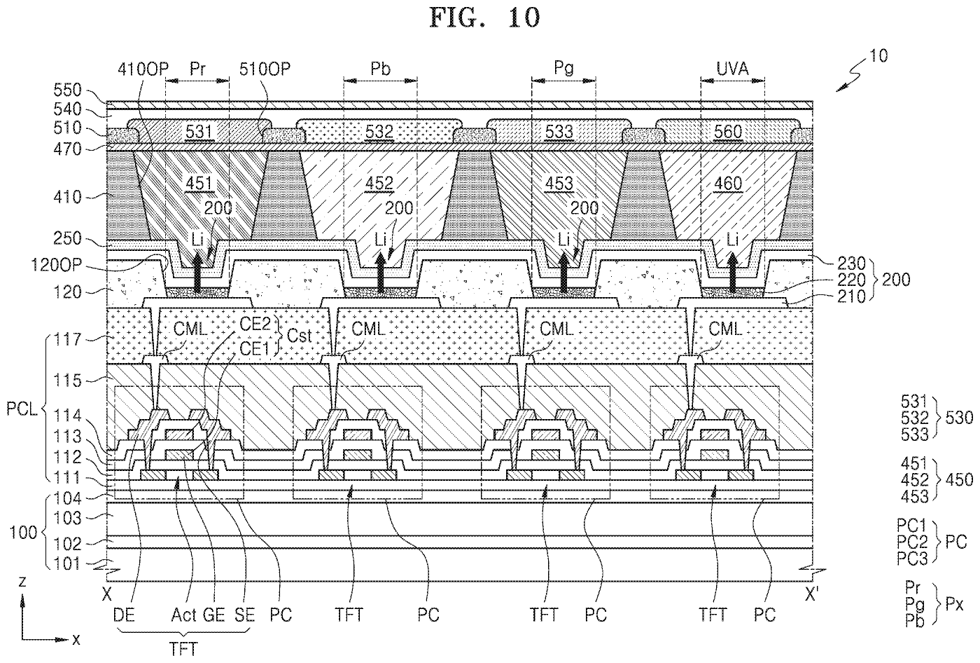

FIG. 10 is a cross-sectional view schematically illustrating a portion of the display panel 10 of FIG. 9, and may correspond to a cross-section of the display panel 10 taken along line X-X′ of FIG. 9. Because the same reference numerals are assigned to the same components as those described with reference to FIG. 5, a description thereof will be omitted, and a description will be made focusing on differences hereinafter.

Referring to FIG. 10, any one of a plurality of light-emitting devices 200, a light-transmitting layer 460, and a dummy color filter layer 560 may be arranged in the ultraviolet area UVA of the display panel 10.

Light emitted from the light-emitting device 200 in the ultraviolet area UVA may be light having a wavelength belonging to about 200 nm to about 220 nm, and may be ultraviolet rays. The light emitted from the light-emitting device 200 in the ultraviolet area UVA may be incident on the light-transmitting layer 460 as the incident light Li. The incident light Li may pass through the light-transmitting layer 460 without changing the wavelength. To this end, the light transmitting layer 460 may not include quantum dots unlike the light conversion layer 450. The light-transmitting layer 460 may include an acrylic resin, an imide resin, or an epoxy resin having light transmittance. The light transmitting layer 460 may be in the opening 4100P of the light shielding wall portion 410.

The incident light Li passing through the light transmitting layer 460 may be emitted to the outside through the dummy color filter layer 560. The dummy color filter layer 560 does not selectively transmit visible light of a specific color like the first, second, and third color filter layers 531, 532, and 533. Therefore, the dummy color filter layer 530 may not include a pigment or a dye. The dummy color filter layer 530 may include an acrylic resin, an imide resin, or an epoxy resin having light transmittance. The dummy color filter layer 530 may be in the opening 5100P of the light shielding layer 510.

Ultraviolet rays emitted from the light-emitting device 200 in the ultraviolet area UVA may be emitted to the outside of the display panel 10 without changing the wavelength. Through this, in addition to an image display function, the display panel 10 may have other functions using ultraviolet rays.

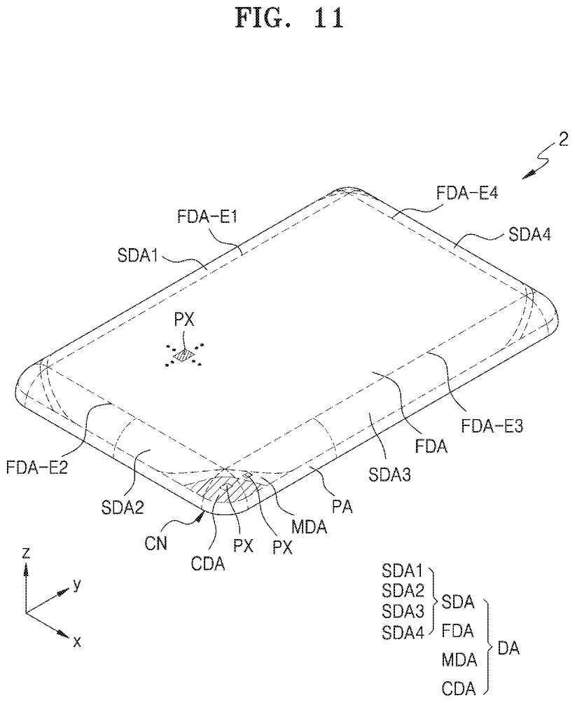

FIG. 11 is a perspective view of a display device according to another embodiment.

Referring to FIG. 11, for example, a display device 2 may have a square shape on a plane. As an alternative embodiment, the display device 2 may have various shapes such as polygons such as triangles and squares, circles, and ellipses. In an embodiment, when the display device 2 has a polygonal shape on a plane, a polygonal corner may be rounded. Hereinafter, for convenience of description, a case in which the display device 2 has a rectangular shape with rounded corners on a plane will be mainly described.

The display device 2 may have a short side in the first direction (e.g., x direction or −x direction) and a long side in the second direction (e.g., y direction or −y direction). In another embodiment, a length of a side in the first direction (e.g., x direction or −x direction) and a length of a side in the second direction (e.g., y direction or −y direction) of the display device 2 may be the same. In another embodiment, the display device 2 may have a long side in the first direction (e.g., x direction or −x direction) and a short side in the second direction (e.g., y direction or −y direction).

A corner where the short side in the first direction (e.g., x direction or −x direction) and the long side in the second direction (e.g., y direction or −y direction) meet may be rounded to have a certain curvature.

A display panel 11 may include the display area DA displaying an image and the peripheral area PA surrounding the display area DA. The plurality of pixels PX may be in the display area DA, and an image may be provided through the plurality of pixels PX. The pixel PX may be defined as an area in which light is emitted by light-emitting devices provided in the display device 2. The light-emitting device of the display device 2 may adopt the structure of the light-emitting device 200 described above with reference to FIG. 5.

The display area DA may include a front display area FDA, a side display area SDA, a corner display area CDA, and a middle display area MDA. The plurality of pixels PX may be disposed in each of the front display area FDA, the side display area SDA, the corner display area CDA, and the middle display area MDA.

The front display area FDA includes a flat surface, and may be disposed, for example, in a center of the display device 2. In an embodiment, a ratio of the front display area FDA to the display area DA of the display device 2 may be the greatest, and thus most of images may be provided.

The side display area SDA includes a curved surface and may extend outward from each edge of the front display area FDA. In an embodiment, the side display area SDA may include a first side display area SDA1, a second side display area SDA2, a third side display area SDA3, and a fourth side display area SDA4. In some embodiments, at least one of the first side display area SDA1, the second side display area SDA2, the third side display area SDA3, and the fourth side display area SDA4 may be omitted.

In an embodiment, the first side display area SDA1 may extend outward in the −x direction from the first edge FDA-E1 of the front display area FDA. The second side display area SDA2 may extend outward in the −y direction from the second edge FDA-E2 of the front display area FDA, the third side display area SDA3 may extend outward in the x direction from the third edge FDA-E3 of the front display area FDA, and the fourth side display area SDA4 may extend outward in the y direction from the fourth edge FDA-E4 of the front display area FDA. In this case, the first side display area SDA1 and the third side display area SDA3 may be located on opposite sides with the front display area FDA therebetween, and the second side display area SDA2 and the fourth side display area SDA4 may be located on opposite sides with the front display area FDA therebetween.

As shown in FIG. 11, each of the first, second, third, and fourth side display areas SDA1, SDA2, SDA3, and SDA4 may include a curved surface that is bent with a constant curvature. For example, the first side display area SDA1 and the third side display area SDA3 may have a curved surface bent around a bending axis extending in the y direction, and the second side display area SDA2 and the fourth side display area SDA4 may have a curved surface bent around a bending axis extending in the x direction. Curvatures of the first to fourth side display areas SDA1, SDA2, SDA3, and SDA4 may be the same or different from each other. For example, the first curvature of the first side display area SDA1 and the third curvature of the third side display area SDA3 may be the same, and the second curvature of the second side display area SDA2 and the fourth curvature of the fourth side display area SDA4 may be the same. For example, the first curvature of the first side display area SDA1 may be different from the second curvature of the second side display area SDA2. As another example, the first curvature of the first side display area SDA1 may be the same as the second curvature of the second side display area SDA2.

The corner display area CDA is at a corner CN of the display device 2 and may include a curved surface. That is, the corner display area CDA may be disposed corresponding to the corner CN. The corner CN may be a portion where the short side in the first direction (e.g., x direction or −x direction) and the long side in the second direction (e.g., y direction or −y direction) meet in the display device 2. In an embodiment, as illustrated in FIG. 9, the display device 2 may have four corners CN, and thus may include four corner display areas CDA.

The corner display area CDA may be disposed adjacent to a portion where adjacent side display areas SDA meet. For example, the four corner display areas CDA may be disposed adjacent to a portion where the first side display area SDA1 and the second side display area SDA2 meet, a portion where the second side display area SDA2 and the third side display area SDA3 meet, a portion where the third side display area SDA3 and the fourth side display area SDA4 meet, and a portion where the fourth side display area SDA4 and the first side display area SDA1 meet, respectively.

Because the corner display area CDA is located between adjacent side display areas SDA having curved surfaces bent in different directions, the corner display area CDA may include a curved surface in which curved surfaces bent in various directions are successively connected. In addition, when the curvatures of adjacent side display areas SDA are different from each other, a curvature of the corner display area CDA may gradually change along an edge of a corresponding corner CN. For example, when the second curvature of the second side display area SDA2 is different from the third curvature of the third side display area SDA3, the corner display area CDA disposed between the second side display area SDA2 and the third side display area SDA3 may have a curvature gradually changing along the edge of the corner CN. For example, when the second curvature of the second side display area SDA2 is less than the third curvature of the third side display area SDA3, the curvature of the corner display area CDA disposed between them may gradually increase in a direction from the second side display area SDA2 to the third side display area SDA3 along the edge of the corner CN. Although the second side display area SDA2 and the third side display area SDA3 and the corner display area CDA therebetween have been described as an example, the disclosure is not limited thereto, and may be applied in the same or similar manner to other side display areas SDA and corner display areas CDA.

The middle display area MDA may be disposed between the corner display area CDA and the front display area FDA. In addition, the middle display area MDA may be between the corner display area CDA and the side display area SDA. In an embodiment, the middle display area MDA may extend between the corner display area CDA and the front display area FDA, and between the side display area SDA and the corner display area CDA.

In an embodiment, the middle display area MDA may include not only the plurality of pixels PX, but also a driver for providing an electric signal or power to each display area DA. In some embodiments, the pixels PX in the middle display area MDA may be disposed to overlap above the driver or the like located in the middle display area MDA.

The display device 2 may display an image not only in the front display area FDA but also in the side display area SDA, the corner display area CDA, and the middle display area MDA. Accordingly, the proportion occupied by the display area DA in the display device 2 may increase. In addition, the display device 2 is bent at a corner and includes the corner display area CDA that displays an image, thereby improving aesthetics.

The display device 2 may include the peripheral area PA outside the display area DA. The peripheral area PA is an area that does not provide an image and may be a non-display area. The peripheral area PA may entirely or partially surround the display area DA. A driver for providing an electric signal or power to the display area DA may be disposed in the peripheral area PA. A pad, which is an area to which an electronic device or a printed circuit board may be electrically connected, may be in the peripheral area PA.

The display device 2 may include a display panel and a cover window. The cover window of the display device 2 may be disposed on the display panel. The cover window may protect the display panel and may be attached to the display panel by a transparent adhesive member. The cover window forms the exterior of the display device 2, and thus may include a flat surface and a curved surface corresponding to the shape of the display device 2 described above.

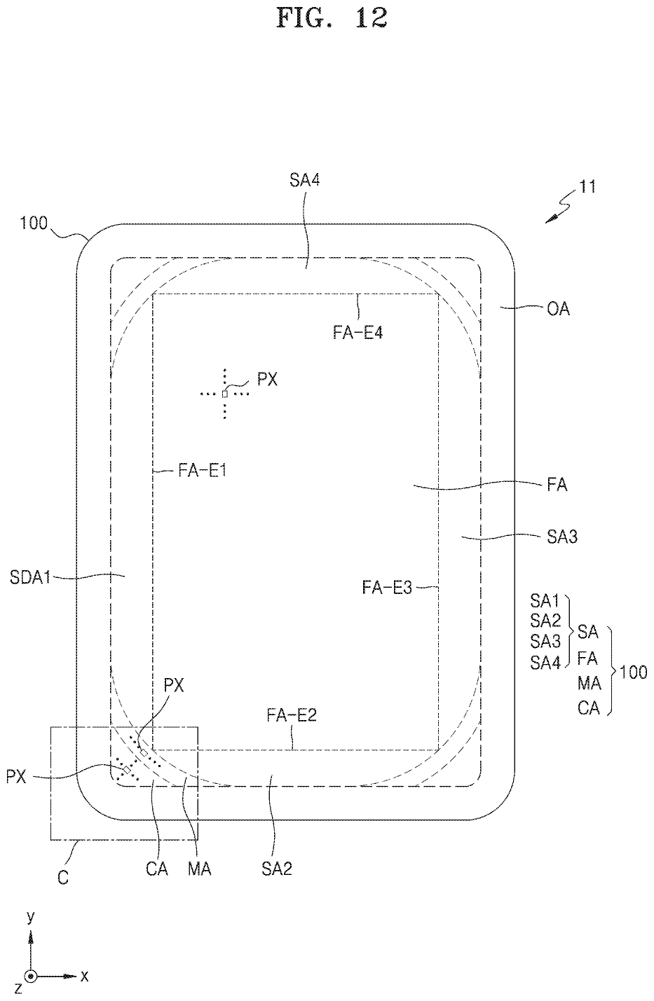

FIG. 12 is a plan view of a display panel according to another embodiment. FIG. 12 illustrates a view of the display panel 11 as viewed from one side, and illustrates an unfolded state before a portion of the display panel 11 is bent.

Referring to FIG. 12, the display panel 11 may include a substrate 100, and several components (not shown) constituting the display panel 11 and a stacked structure thereof may be on the substrate 100. A stacked structure of the display panel 11 may be the same as or similar to a stacked structure of the display panel 10 described above with reference to FIG. 5.

The substrate 100 may include various areas FA, SA, CA, and OA corresponding to the display area DA (see FIG. 11) of the display device 2 (see FIG. 11) described above with reference to FIG. 11 and the peripheral area PA (see FIG. 11). In an embodiment, as shown in FIG. 12, the substrate 100 may include the front area FA, the side area SA, the corner area CA, the middle area MA, and the outer area OA.

The front area FA of the substrate 100 is disposed in a center of the substrate 100 and may correspond to the front display area FDA (see FIG. 11) of the display device 2. In an embodiment, similar to the front display area FDA of the display device 2, the front area FA of the substrate 100 may have a rectangular shape on a plane.

The side area SA of the substrate 100 may extend outwardly from each of the edges of the front area FA, and may correspond to the side display area SDA of the display device 2. In an embodiment, the side area SA of the substrate 100 may include a first side area SA1, a second side area SA2, a third side area SA3, and a fourth side area SA4. The first side area SA1 may extend outward in the −x direction from an first edge FA-E1 of the front area FA, the second side area SA2 may extend outward in the −y direction from a second edge FA-E2 of the front area FA, the third side area SA3 may extend outward in the x direction from a third edge FA-E3 of the front area FA, and the fourth side area SA4 may extend outward in the y direction from a fourth edge FA-E4 of the front area FA.

The corner area CA of the substrate 100 may be located outside a portion of side areas SA where two adjacent side areas SA meet, and may correspond to the corner display area CDA of the display device 2. In an embodiment, the substrate 100 may include four corner areas CA as shown in FIG. 12. The four corner areas CA may be located outside a portion where the first side area SA1 and the second side area SA2 meet, outside a portion where the second side area SA2 and the third side area SA3 meet, outside a portion where the third side area SA3 and the fourth side area SA4 meet, and outside a portion where the fourth side area SA4 and the first side area SA1 meet, respectively.

The middle area MA of the substrate 100 may be disposed between the front area FA and the corner area CA. In addition, the middle area MA of the substrate 100 may be located between the side area SA and the corner area CA. In an embodiment, the middle area MA may extend between the front area FA and the corner area CA, and disposed between the side area SA and the corner area CA. The middle area MA may connect the front area FA, two adjacent side areas SA, and one corner area CA.

The outer area OA of the substrate 100 is disposed outside the front area FA, the side areas SA, and the corner areas CA, and may entirely or partially surround them. The outer area OA of the substrate 100 may correspond to the peripheral area PA of the display device 2.

The plurality of pixel circuits PC and the plurality of light-emitting devices 200 (see FIG. 5) electrically and respectively connected to the pixel circuits PC are arranged in the front area FA, the side areas SA, and the corner areas CA of the substrate 100. As described above, the light-emitting device 200 receiving a driving current from the pixel circuit PC may emit light, and a light-emitting area in which light is emitted by the light-emitting device 200 may be defined as the pixel PX. Accordingly, the front area FA, the side areas SA, and the corner areas CA of the substrate 100 may overlap the plurality of pixels PX. An area where the pixel PX is disposed may display an image through light, so that the display area DA may be formed. Accordingly, the front area FA, the side areas SA, and the corner areas CA of the substrate 100 may respectively correspond to the front display area FDA, the side display areas SDA, and the corner display areas CDA.

The plurality of light-emitting devices 200 may be disposed in the middle areas MA of the substrate 100, and thus, the middle area MA may overlap the plurality of pixels PX. Furthermore, in an embodiment, a driver (not shown) for providing an electrical signal and/or a power wire (not shown) for providing a voltage may also be disposed in the middle area MA. For example, the driver may be a scan driver that provides a scan signal. In this case, the pixels PX disposed in the middle area MA may overlap the driver and/or the power wire. In some embodiments, the plurality of pixel circuits PC for driving the plurality of light-emitting devices 200 disposed in the middle area MA may be located in the corner areas CA adjacent to the middle area MA, the side areas SA, and/or the front area FA.

A driver for providing an electric signal or power to the display area DA, a power wire for providing a voltage, and the like may be disposed in the outer area OA of the substrate 100. The driver disposed in the outer area OA may include a scan driver providing a scan signal and a data driver providing a data signal. In addition, a pad, which is an area to which an electronic device or a printed circuit board may be electrically connected, may be disposed in the outer area OA. The light-emitting devices 200 are not disposed in the outer area OA, and thus the outer area OA may overlap a non-display area.

In order to manufacture the display device 2 of FIG. 11, at least a portion of the substrate 100 of the display panel 10 may be bent. For example, the first side area SA1 and the third side area SA3 of the substrate 100 may be bent at a certain curvature around a bending axis extending in the y direction, and the second side area SA2 and the fourth side area SA4 may be bent at a certain curvature around a bending axis extending in the x direction. In this case, the corner areas CA of the substrate 100 may form curved surfaces that are continuously bent in various directions. In addition, when curvatures of the first side area SA1 and the third side area SA3 of the substrate 100 are different from curvatures of the second side area SA2 and the fourth side area SA4, the corner areas CA of the substrate 100 may have curvatures that change along respective edges of corresponding corner areas CA.

In order to form the corner area CA having different bending directions and/or different curvatures in this way, the corner area CA of the substrate 100 need to be capable of both contraction and stretching. Because both compressive strain and tensile strain occur in the corner area CA of the substrate 100, in order to prevent damage to components disposed on the corner areas CA of the substrate 100, the corner areas CA of the substrate 100 need to be capable of both contraction and stretching.

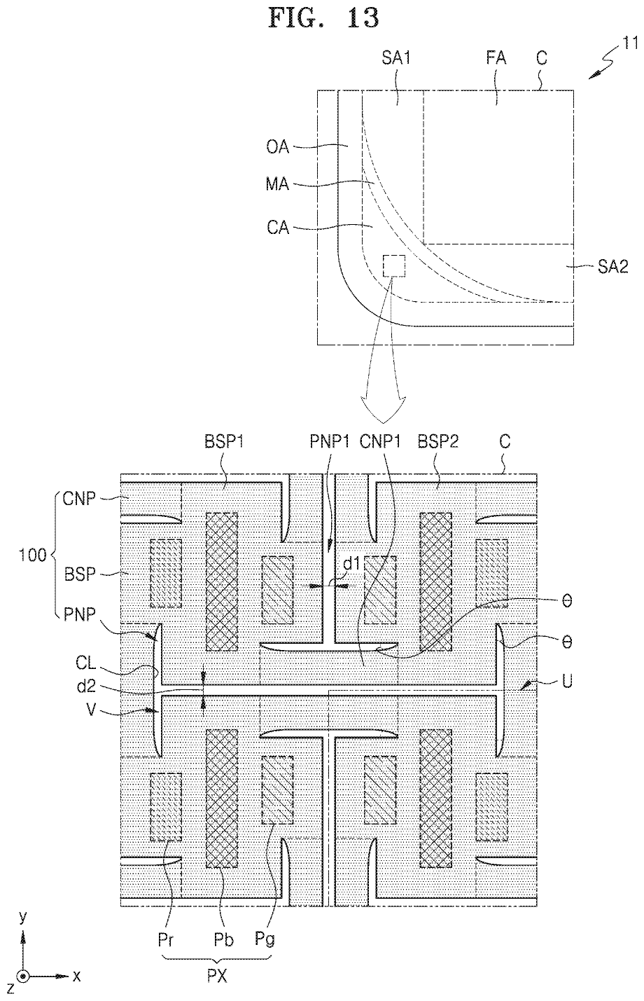

FIG. 13 is an enlarged plan view of a portion of the display panel 11 of FIG. 12. Area C of FIG. 13 may correspond to area C of FIG. 12.

Referring to FIG. 13, in order to prevent damage to components disposed on the corner areas CA of the substrate 100, the substrate 100 may adopt the structure described above with reference to FIGS. 3B and 3C. That is, the substrate 100 may include a flexible material, for example, a polymer resin. In addition, the substrate 100 may include the plurality of through portions PNP and the plurality of base portions BSP spaced apart from each other by the plurality of through portions PNP, and each of the plurality of connection portions CNP extending in different directions from the plurality of base portions BSP.

Through this, because the substrate 100 is capable of both contraction and stretching, even if the corner areas CA of the substrate 100 are bent, damage to components disposed on the corner areas CA of the substrate 100 may be prevented. Because the components may be disposed in the corner areas CA without damage, the pixels PX may be stably formed in the corner area CA. Accordingly, the corner display area CDA of the display device 2 (see FIG. 11) may be implemented, and through this, the display area DA of the display device 2 may be expanded.

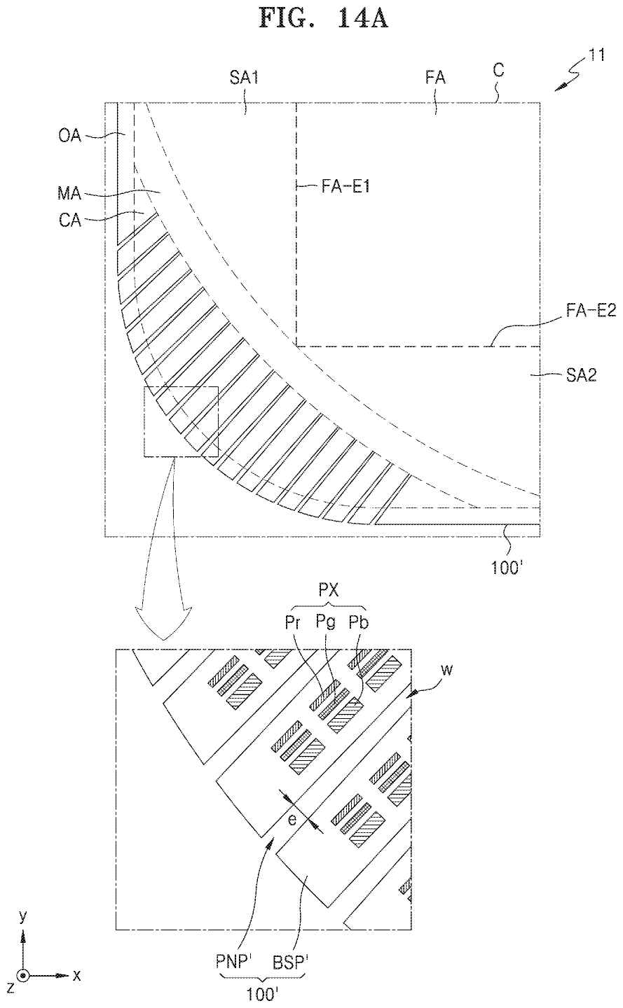

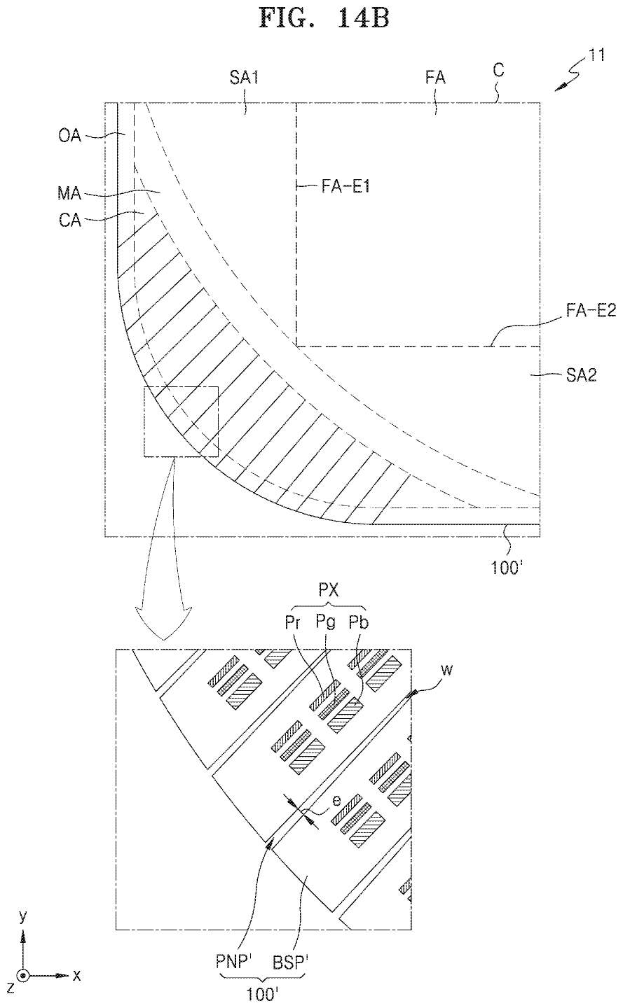

FIGS. 14A and 14B are enlarged plan views of a portion of a display panel according to another embodiment. Area C of FIGS. 14A and 14B may correspond to area C of FIG. 12. FIG. 14A shows a state before the display panel is bent, and FIG. 14B shows a state after the display panel is bent and deformed.

Referring to FIG. 14A, the display panel 11 may include a substrate 100′ including a plurality of through portions PNP′ and a plurality of base portions BSP′ spaced apart from each other by the plurality of through portions PNP′. In an embodiment, the plurality of through portions PNP′ and the plurality of base portions BSP′ of the substrate 100′ are located in the corner area CA of the substrate 100′, but may extend outward away from the front area FA of the substrate 100′.

For example, each of the plurality of base portions BSP′ may have a shape extending outward away from the front area FA of the substrate 100′. That is, an extension length of the plurality of base portions BSP′ may be greater than a width in a direction crossing the extension direction. One end of the plurality of base portions BSP′ may be connected to a portion of the substrate 100′, and the other end may form a corner of the substrate 100.

The plurality of base portions BSP′ may be arranged parallel to each other, or may be radially arranged. In an embodiment, when the plurality of base portions BSP′ are arranged parallel to each other, a distance “e” disposed between two adjacent base portions BSP′ may be constant in an extending direction of the base portion BSP′. In another embodiment, when the plurality of base portions BSP′ are arranged radially, the distance “e” disposed between the two adjacent base portions BSP′ may gradually increase in the extending direction of the base portion BSP′. Hereinafter, for convenience of description, a case in which the plurality of base portions BSP′ are arranged radially as shown in FIG. 14A will be described.

Components such as a pixel circuit, light-emitting device, and signal wire may be disposed on the plurality of base portions BSP′, and the plurality of pixels PX may be disposed on the plurality of base portions BSP′, respectively. The corner display area CDA (see FIG. 11) may be implemented by the pixels PX disposed on the plurality of base portions BSP′.

A through portion PNP′ may be disposed between two adjacent base portions BSP′ from among the plurality of base portions BSP′. The through portion PNP′ may be defined by the two adjacent base portions BSP′ and a portion of the substrate 100′ connected to the two base portions BSP′. The through portion PNP′ may extend in an extending direction of the base portion BSP′. The through portion PNP′ may penetrate upper and lower surfaces of the display panel 11 and may reduce the weight of the display panel 11. By the through portion PNP′, two adjacent base portions BSP′ from among the plurality of base portions BSP′ may be apart from each other by the certain distance “e”. The through portion PNP′ may provide a separation area W between the two adjacent base portions BSP′. That is, each of the through portions PNP′ may overlap the separation area W.

Referring to FIG. 14B, when an external force (e.g., a force such as bending or compressing) is applied to the display panel 11, positions of the plurality of base portions BSP′ may change, and the shape of a separation area W′ between the two adjacent base portions BSP′ may change. Through this, both shrinkage and stretch characteristics may be provided to the display panel 10. For example, as an external force is applied to the base portions BSP′, each of the base portions BSP′ may be stretched in an extension direction, and at the same time, as an area of the separation area W′ between the two adjacent base portions BSP′ decreases, the effect of contraction may be achieved. In addition, in some embodiments, the base portions BSP′ may be bent by different curvatures.

Through this structure of the substrate 100′, even if the corner area CA of the substrate 100′ is bent, damage to components disposed on the corner areas CA of the substrate 100′ may be prevented. Because the components may be disposed in the corner areas CA of the substrate 100′ without damage, the pixels PX may be stably formed in the corner area CA. Accordingly, the corner display area CDA of the display device 2 (see FIG. 11) may be implemented, and through this, the display area DA of the display device 2 may be expanded.

According to the embodiment as described above, a display panel may be stretched and contracted, and an organic encapsulation layer may be unnecessary by adopting an inorganic light-emitting device as a light-emitting device. Through this, it is possible to improve resolution and flexibility, further implement a display panel in which a display area is expanded, and a display device including the same, and implement a method of manufacturing the display panel. However, the scope of the disclosure is not limited to the effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate including a plurality of through portions and a plurality of base portions spaced apart from each other by the plurality of through portions;
a pixel electrode disposed on the substrate;
an opposite electrode disposed on the pixel electrode; and
a light-emitting layer disposed between the pixel electrode and the opposite electrode and including an inorganic semiconductor material having a grain boundary.

2. The display panel of claim 1, wherein the inorganic semiconductor material of the light-emitting layer includes polycrystalline aluminum nitride (AlN) doped with silicon (Si) or polycrystalline gallium nitride (GaN) doped with Si.

3. The display panel of claim 1, wherein a thickness of the light-emitting layer is about 100 Å or less.

4. The display panel of claim 1, wherein the pixel electrode includes aluminum (Al) or gallium (Ga).

5. The display panel of claim 1, wherein the opposite electrode includes indium tin oxide (ITO), indium zinc oxide (IZO), zinc oxide (ZnO), indium oxide (In₂O₃), indium gallium oxide (IGO), or aluminum zinc oxide (AZO).

6. The display panel of claim 1, further comprising a light conversion layer disposed on the opposite electrode and overlapping the light-emitting layer.

7. The display panel of claim 6, wherein the light conversion layer includes a first light conversion layer, a second light conversion layer, and a third light conversion layer each having scattering particles,
wherein the first, second, and third light conversion layers further include first, second, and third quantum dots including a same material but having different sizes, respectively.

8. The display panel of claim 6, further comprising a capping layer disposed between the opposite electrode and the light conversion layer and contacting the opposite electrode and the light conversion layer, respectively.

9. The display panel of claim 1, wherein the substrate further includes a plurality of connection portions extending in different directions from the plurality of base portions, respectively, and
wherein two adjacent base portions from among the plurality of base portions are spaced apart from each other with any one of the plurality of through portions therebetween, and at least one of the plurality of connecting portions connects the two adjacent base portions to each other.

10. The display panel of claim 1, wherein the substrate includes:
a front area in a center;
side areas extending outward from edges of the front area, respectively; and
corner areas connecting two adjacent side areas to among the side areas,
wherein the plurality of through portions and the plurality of base portions of the substrate are located in the corner area and extend outward away from the front area.

11. A display device comprising:
a display panel; and
a cover window disposed on the display panel,
wherein the display panel includes:
a substrate having a plurality of through portions and a plurality of base portions spaced apart from each other by the plurality of through portions;
a pixel electrode disposed on the substrate;
an opposite electrode disposed on the pixel electrode; and
a light-emitting layer disposed between the pixel electrode and the opposite electrode and including an inorganic semiconductor material having a grain boundary.

12. The display device of claim 11, wherein the inorganic semiconductor material of the light-emitting layer includes polycrystalline aluminum nitride (AlN) doped with silicon (Si) or polycrystalline gallium nitride (GaN) doped with Si.

13. The display device of claim 11, wherein a thickness of the light-emitting layer is about 100 Å or less.

14. The display device of claim 11, wherein the pixel electrode includes aluminum (Al) or gallium (Ga).

15. The display device of claim 11, further comprising a light conversion layer disposed on the opposite electrode and overlapping the light-emitting layer.

16. The display device of claim 15, further comprising a capping layer interposed between the opposite electrode and the light conversion layer and contacting the opposite electrode and the light conversion layer, respectively.

17. The display device of claim 11, wherein the substrate further includes a plurality of connection portions extending in different directions from the plurality of base portions, respectively, and
wherein two adjacent base portions from among the plurality of base portions are apart from each other with any one of the plurality of through portions therebetween, and at least one of the plurality of connecting portions connects the two adjacent base portions to each other.

18. The display device of claim 11, wherein the substrate includes:
a front area in a center;
side areas extending outward from edges of the front area, respectively; and
a corner area disposed outside an area where two adjacent side areas meet from among the side areas,
wherein the plurality of through portions and the plurality of base portions of the substrate are located in the corner area and extend outward away from the front area.

19. A method of manufacturing a display panel, the method comprising steps of:
preparing a substrate including a plurality of through portions and a plurality of base portions spaced apart from each other by the plurality of through parts;
forming a pixel electrode including aluminum or gallium disposed on the substrate;
forming a light-emitting layer disposed on the pixel electrode; and
forming a opposite electrode disposed on the light-emitting layer,
wherein the forming of the light-emitting layer is accomplished by
forming a material layer including silicon nitride (SiNx) disposed on the pixel electrode, and
irradiating a laser beam onto the material layer.

20. The method of claim 19, wherein a thickness of the light-emitting layer is about 100 Å or less.

21. The method of claim 19, wherein the light-emitting layer includes an inorganic semiconductor material having polycrystalline aluminum nitride (AlN) doped with silicon (Si) or polycrystalline gallium nitride (GaN) doped with Si.

22. The method of claim 19, further comprising steps of:
forming a capping layer disposed on the opposite electrode; and
forming a light conversion layer overlapping the light-emitting layer on the capping layer,
wherein the capping layer contacts the opposite electrode and the light conversion layer, respectively.

23. The method of claim 19, wherein the substrate further includes a plurality of connection portions extending in different directions from the plurality of base portions, respectively, and
wherein two adjacent base portions from among the plurality of base portions are apart from each other with any one of the plurality of through portions therebetween, and at least one of the plurality of connecting portions connects the two adjacent base portions to each other.

24. The method of claim 19, wherein the substrate includes:
a front area in a center;
side areas extending outward from edges of the front area, respectively; and
corner areas connecting two adjacent side areas to among the side areas,
wherein the plurality of through portions and the plurality of base portions of the substrate are located in the corner area and extend outward away from the front area.
